(19) United States
(12) Patent Application Publication
(10) Pub. No.: US 2011/0198756 A1
(43) Pub. Date: Aug. 18, 2011

(54) Organometallic Precursors and Related Intermediates for Deposition Processes, Their Production and Methods of Use

(76) Inventors: ü Thenappan, München, NJ (US); Chien-Wei Li, Vienna, VA (US); David Nalewajek, West Seneca, NY (US); Martin Cheney, Hamburg, NY (US); Jingyu Lao, Saline, MI (US); Eric Eisenbraun, Albany, NY (US); Min Li, Troy, MI (US); Nathaniel Berliner, Albany, NY (US); Mikko Ritala, Espoo (FI); Markku Leskela, Espoo (FI); kaupo Kukli, Polva (EE); Linda Cheney, Hamburg, NY (US)

(21) Appl. No.: 12/067,285

(22) PCT Filed: Aug. 25, 2006
(86) PCT No.: PCT/US06/33207

§ 371 Date: Mar. 10, 2011

Related U.S. Application Data
(60) Provisional application No. 60/740,172, filed on Nov. 28, 2005.
(60) Provisional application No. 60/740,206, filed on Nov. 28, 2005.
(60) Provisional application No. 60/799,912, filed on May 12, 2006.

(51) Int. Cl. H01L 21/3205; H01L 29/43; H01L 23/48

(52) U.S. Cl. 257/751; 438/681; 257/769; 257/E21.294; 257/E23.01; 257/E29.139

(57) ABSTRACT

Vapor deposition precursors that can deposit conformal thin ruthenium films on substrates with a very high growth rate, low resistivity and low levels of carbon, oxygen and nitrogen impurities have been provided. The precursors described herein include a compound having the formula CMC′, wherein M comprises a metal or a metalloid; C comprises a substituted or unsubstituted acyclic alkene, cycloalkene or cycloalkene-like ring structure; and C′ comprises a substituted or unsubstituted acyclic alkene, cycloalkene or cycloalkene-like ring structure; wherein at least one of C and C′ further and individually is substituted with a ligand represented by the formula CH(X)R₁, wherein X is a N, P, or S-substituted functional group or hydroxyl, and R₁ is hydrogen or a hydrocarbon. Methods of production of the vapor deposition precursors and the resulting films, and uses and end uses of the vapor deposition precursors and resulting films are also described.

This PCT application claims priority to U.S. Provisional Application Ser. Nos. 60/740,172 filed on Nov. 28, 2005, 60/740,206 filed on Nov. 28, 2005 and U.S. Provisional Application Ser. No. 60/799,912 filed on May 12, 2006, which are all commonly-owned and incorporated herein by reference in their entirety.

### FIELD OF THE SUBJECT MATTER

The field of the subject matter disclosed herein relates to formation of organometallic films, such as ruthenium and related thin films, by vapor deposition from organometallic precursors and related intermediates. These films can be used in the microelectronics industry.

### BACKGROUND

Vapor deposition, specifically atomic layer deposition (ALD), is used to fabricate conformal and ultra-thin film structures for many semiconductor and thin film device applications. A unique attribute of ALD is that it uses sequential self-limiting surface reactions to achieve control of film growth in the monolayer or sub-monolayer thickness regime. ALD is receiving attention for its potential applications in advanced high dielectric constant (high-k) gate oxides and gate metals, storage capacitor dielectrics and gate electrodes, and copper diffusion barriers/seeds in advanced electronic devices. It is also of interest in any advanced application that benefits from excellent step coverage (conformality), accurate thickness control of film structure in the nanometer or sub nanometer scale and large-area uniformity.

Organometallic precursor materials used for atomic layer deposition should have sufficient volatility and thermal stability. Additionally, the precursor material should be sufficiently reactive with a variety of reactants, such as H₂, O₂, O₃, H₂O, H₂O₂, N₂O, NH₃, N₂H₄, PH₃, SiH₄, Si₂H₆, CH₃SiH₃, ClSiH₃, Cl₂SiH₂, BH₃, B₂H₆, N₂ plasma, Ar plasma and the like, which convert the organometallic precursor material to either the metal, metal nitride, metal silicide or metal oxide.

Based on the combination of the potential of ALD with the properties of organometallic precursor materials, the industry sought to find or develop an organometallic compound that has the right combination of thermal stability, volatility and reactivity for the types of applications described herein. Ruthenium (Ru) metal is a good candidate to form the foundation of these organometallic compounds, because ruthenium is a candidate material for capacitor electrodes in dynamic random access memories (DRAM) and in ferroelectric random access memories (FRAM). Ruthenium or ruthenium alloy materials are also considered as gate electrode materials for logic applications due to its high work function, and conductive ruthenium oxide films have shown effective oxygen diffusion barrier properties. Ruthenium metal is also considered as a copper barrier, seed and/or glue material candidate that may replace the current Ta/Cu bi-layer in the copper interconnect application to reduce the total barrier layer thickness and cost. This promise is in part due to ruthenium's excellent characteristics such as low resistivity, large work function, high resistance to oxidation, strong adherence to Cu and TaN, and good dry etching properties. Furthermore, ruthenium metal is a strong candidate in the next generation contact plug application. Ruthenium metal is also a candidate as the channel layer and electrode for the Magnetic RAM (MRAM) application.

Deposition of ruthenium films from ruthenium-based precursors are described in U.S. Pat. No. 6,440,495 to Wade, et al., U.S. Pat. No. 6,074,945 to Vaaetstra et al., U.S. Pat. No. 6,824,816 B2 to Mikko Ritala et al., U.S. Pat. No. 7,074,719 to Kim and Rossnagel, U.S. Pat. No. 6,605,735 to Kawano et al, U.S. Pat. No. 6,800,542 to Kim, U.S. Pat. No. 6,840,988 to Marsh and Uhlenbrock, World Patent Applications WO 2005/020317 A2 to Chang et al., and WO 20041041753 to Thompson et al. Although some examples of organometallic ruthenium precursors for ALD and other chemical vapor deposition methods exist, it is generally acknowledged by those skilled in the art that a more reactive, volatile, and thermally stable ruthenium precursor is needed that can react with suitable reactants under ALD conditions to produce highly uniform, conductive, pure and conformal ruthenium metal film in the manufacturing of various semiconductor devices. In addition, it has been difficult to maximize the deposition rate for conventional precursors, while at the same time create a useful and uniform film. It is known that the ALD processes using conventional ruthenium precursors have the problem of long incubation times at the beginning of ruthenium film growth, resulting in non-continuous ruthenium film where the thickness is less than about 5 nm. Furthermore, it is known that the conventional ruthenium precursors and their ALD processes generate ruthenium films with growth rates too low to be used in the commercial volume production. Lastly, it is known that the conventional ruthenium precursors and their ALD processes may lead to ruthenium films with roughness, resistivity and impurity concentrations too high to be used in the advanced semiconductor chip applications.

When determining whether an organometallic precursor will be useful in film formation, several goals should be reviewed: a) the precursors should be vaporizable, b) the precursors should be thermally stable in all types of vapor deposition processes, such as CVD, ALD, AVD (Atomic Vapor Deposition), etc., c) useful precursors should contain an organic moiety (or a group) that can be functionalized to allow for the tailoring of properties to suit the chemistry of the substrate being employed in the deposition process, d) properties, such as volatility, reactivity, thermal stability, and reduction/oxidation potentials, should be maximized and tailored in order to provide an optimized compound for a specific application, and e) deposition parameters should be tailored in order to maximize the growth rate, while minimizing the resistivity and harmful impurities. Unfortunately, these goals have not been realized in any of the conventional organometallic precursors known to date.

Therefore to meet the needs of the various industries requirements of forming metal film using ALD and the more general chemical vapor deposition (CVD) techniques, a new class of organometallic precursors and related intermediates have been developed. These precursors exhibit high growth rates and the deposited films by ALD have good conformality, low resistivity and low concentrations of carbon, oxygen and nitrogen impurities. In addition, several synthetic routes disclosed herein are novel with respect to these organometallic precursors.

### SUMMARY OF THE SUBJECT MATTER

Vapor deposition precursors that can deposit conformal thin ruthenium films on substrates with a very high growth rate, low resistivity and low levels of carbon, oxygen and nitrogen impurities have been provided. The precursors described herein include a compound having the formula CMC′, wherein M comprises a metal or a metalloid; C comprises a substituted or unsubstituted acyclic alkene, cycloalkene or cycloalkene-like ring structure; and C′ comprises a substituted or unsubstituted acyclic alkene, cycloalkene or cycloalkene-like ring structure; wherein at least one of C and C′ further and individually is substituted with a ligand represented by the formula CH(X)R₁, wherein X is a N, P, or S-substituted functional group or hydroxyl, and R₁ is hydrogen or a hydrocarbon.

Methods of production of the vapor deposition precursors and the resulting films, and uses and end uses of the vapor deposition precursors and resulting films are also described.

### BRIEF DESCRIPTION OF THE FIGURES

FIG. 1A shows a contemplated vapor deposition precursor comprising an organometallic compound. In this Figure, C and C′ are represented as substituted cyclopentadienes.

FIG. 1B shows a contemplated vapor deposition precursor comprising an organometallic compound. In this Figure, C is a substituted cyclopentadiene and C′ is a linear diene.

FIG. 2 shows a synthesis of a contemplated organometallic compound.

FIG. 3 shows a synthesis of a contemplated organometallic compound.

FIG. 4 shows a contemplated synthesis of the substituted ruthenocene, where R₁═R₂, the ruthenocene can be prepared by treating the symmetrically substituted bis(acetate) with an amine.

FIG. 5 shows plotted growth rates for Runs 13-16 in the incubation/seed period, as discussed in Example 31.

### DETAILED DESCRIPTION

A new series of organometallic compounds, which have application as chemical vapor deposition precursors and more specifically as atomic layer deposition precursors, have been developed and their uses are described herein. The phrase “vapor deposition” or “chemical vapor deposition” or “CVD” as used herein refers to the general class of deposition techniques including ALD, MOCVD, liquid injection MOCVD, AVD, liquid injection ALD and the like. The abbreviation “MO” refers to the general class of compounds known as metal-organic. ALD techniques can include thermal ALD, plasma-enhanced ALD (PEALD) and hybrids thereof.

### Organometallic Compounds & their Synthesis

Compounds as contemplated herein, especially those that can be utilized as vapor deposition precursors which comprise organometallic compounds, have the general formula CMC′ (Formula 1). As represented in Formula 1, M is a metal or metalloid, C comprises a substituted or unsubstituted acyclic alkene, a cycloalkene or a cycloalkene-like ring structure, C′ comprises a substituted or unsubstituted acyclic alkene, a cycloalkene or a cycloalkene-like ring structure.

As shown in Formula 1, C and C′ may be the same or different and each may represent a linear or straight chain alkenyl or a cycloalkenyl ring with or without a substituent. Accordingly, the disclosure herein describes a metallocene like organometallic compound wherein C and C′ are cycloalkene or cycloalkene-like ring structure and a half-sandwich organometallic compound wherein C or C′ is a acyclic alkene. Substituted ring contains a donor group substituted ligand represented by a formula CH(X)R₁, wherein X is a donor group, R₁ is hydrogen or hydrocarbon chain. As used herein, the terms “cycloalkene” and “cycloalkene-like” may represent any suitable structure that is considered as part of that group of compounds by those of ordinary skill in the art. However, in some embodiments, these terms refer to cyclopentadiene, cycloheptatriene, cycloctatetraene and indene. Contemplated donor groups comprise OH, SH, NH₂, NH(R₂), N(R₂R₃), or any hetero atom substituted functional group.

In some embodiments, M comprises ruthenium (Ru), osmium (Os), iron (Fe), rhenium (Re), cobalt (Co), rhodium (Rh), iridium (Ir), nickel (Ni), platinum (Pt), palladium (Pd), copper (Cu), silver (Ag), gold (Au), zinc (Zn), cadmium (Cd), mercury (Hg), aluminum (Al), germanium (Ge), titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), barium (Ba), strontium (Sr), bismuth (Bi), calcium (Ca), lead (Pb), gallium (Ga) and indium (In). In other embodiments, M comprises elements from the lanthanide or actinide series of the Periodic Chart of the Elements.

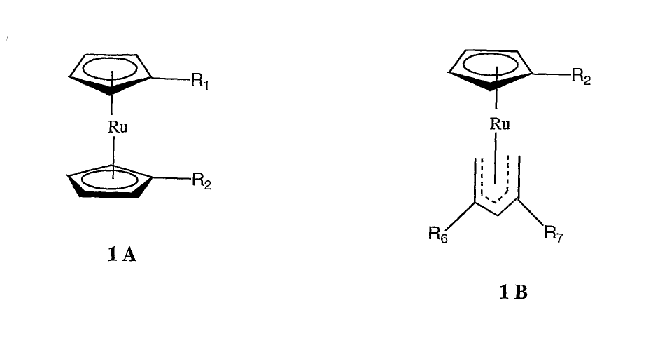

These new compounds shown in Formula 1, such as vapor deposition precursors comprising organometallic compounds, can be represented by the following structure, as shown in FIGS. 1A & 1B. In FIGS. 1A, C and C′ are represented as substituted cyclopentadienes and in FIG. 1B, C is a substituted cyclopentadiene and C′ is a linear diene.

In FIG. 1A, R₁ comprises H or R₂, R₂ comprises CH(X) R₃, X comprises OH, SH, nitrogen or any hetero atom substituted donor group, R₃ comprise hydrogen or a hydrocarbon with at least one primary alkyl group, secondary alkyl group, tertiary alkyl group or cycloalkyl group; and wherein M comprises at least one group 8 metal from the Periodic Chart of the Elements.

In other contemplated embodiments, R₁ comprises H or R₂, R₂ comprises CH(OH)R₃ or, CH[NR₄R₅]R₃, R₄ and R₅ may be the same or different and comprise at least one primary alkyl group, secondary alkyl group, tertiary alkyl group or cycloalkyl group; and wherein M comprises at least one group 8 metal from the Periodic Chart of the Elements. In some embodiments, R₄ and R₅ can be the same or different and comprise primary, secondary and tertiary alkyl groups with a general formula CₙH₂ₙ₊₁ where n=1-6 and cycloalkyl. R₃ may comprise hydrogen or a primary, secondary and tertiary alkyl groups with a general formula CₙH₂ₙ₊₁ where n=1-6 and cycloalkyl. Contemplated alkyl groups include: CH₃, C₂H₅, C₃H₇, C₄H₉, C₅H₁₁, C₆H₁₁ etc, and M comprises Group 8 metals of the periodic table, such as iron (Fe), ruthenium (Ru) and osmium (Os).

In FIG. 1B, R₂ comprises CH(X)R₃, X comprises OH, SH, nitrogen or any hetero atom substituted donor group, R₃ comprise hydrogen or a hydrocarbon with at least one primary alkyl group, secondary alkyl group, tertiary alkyl group or cycloalkyl group; R₆ and R₇ may be the same or different and comprise at least one primary alkyl group, secondary alkyl group, tertiary alkyl group or cycloalkyl group and wherein M comprises at least one group 8 metal from the Periodic Chart of the Elements. In other contemplated embodiments, R₂ comprises CH(OH)R₃ or, CH[NR₄R₅]R₃, R₄ and R₅ may be the same or different and comprise at least one primary alkyl group, secondary alkyl group, tertiary alkyl group or cycloalkyl group; R₆ and R₇ may be the same or different and comprise at least one primary alkyl group, secondary alkyl group, tertiary alkyl group or cycloalkyl group and wherein M comprises at least one group 8 metal from the Periodic Chart of the Elements. In some embodiments, R₄ and R₅ can be the same or different and comprise primary, secondary and tertiary alkyl groups with a general formula CₙH₂ₙ₊₁ where n=1-6 and cycloalkyl. R₆ and R₇ may be the same or different and comprise primary, secondary and tertiary alkyl groups with a general formula CₙH₂ₙ₊₁ where n=1-6 and cycloalkyl. R₃ may comprise hydrogen or a primary, secondary and tertiary alkyl groups with a general formula CₙH₂ₙ₊₁ where n=1-6 and cycloalkyl. Contemplated alkyl groups include: CH₃, C₂H₅, C₃H₇, C₄H₉, C₅H₁₁, C₆H₁₁ etc, and M comprises Group 8 metals of the periodic table, such as iron (Fe), ruthenium (Ru) and osmium (Os).

In FIG. 1A, the symmetrically substituted organometallic, also referred to as a metallocene, is obtained when R₁═R₂ and R₁ is not hydrogen. The asymmetrically substituted metallocene precursor is obtained when R₁ does not equal R₂ and R₁ may be hydrogen. It should be noted that in the above FIG. 1A, the metallocene is depicted in its staggered configuration. Metallocenes can also have an eclipsed configuration, as is well known to those skilled in the art. As used herein, the formula, which is presented, is not intended to depict a particular metallocene configuration. FIG. 1B provides a half-sandwich organometallic compound wherein one of the substituents attached to the metal is an acyclic alkene. In some embodiments, the formula shown above results in the following contemplated compounds: C₅H₅RuC₅H₄CH(OH)CH₃ or C₅H₅RuC₅H₄CH[N(CH₃)₂]CH₃ or C₅H₅RuC₅H₄CH[N(CH₃)(C₂H₅)]CH₃ or C₅H₅RuC₅H₄CH[N(ⁿC₄H₉)(CH₃)]CH₃ or C₅H₅RuC₅H₄CH[N(C₂H₅)₂]CH₃ or C₅H₅RuC₅H₄CH₂[N(CH₃)₂] or C₅H₅RuC₅H₄CH₂[N(CH₃)(C₂H₅)] or C₅H₅RuC₅H₄CH₂[N(ⁿC₄H₉)(CH₃)] or C₅H₅RuC₅H₄CH₂[N(C₂H₅)₂] or [CH₂═C(CH₃)CHC(CH₃)═CH₂]RuC₅H₄CH(OH)CH₃ or [CH₂═C(CH₃)CHC(CH₃)═CH₂]RuC₅H₄CH[N(CH₃)₂]CH₃ or [CH₂═C(CH₃)CHC(CH₃)═CH₂]RuC₅H₄CH[N(CH₃)(C₂H₅)]CH₃ or [CH₂═C(CH₃)CHC(CH₃)═CH₂]RuC₅H₄CH[N(ⁿC₄H₉)(CH₃)]CH₃ or [CH₂═C(CH₃)CHC(CH₃)═CH₂]RuC₅H₄CH[N(C₂H₅)₂]CH₃ or [CH₂═C(CH₃)CHC(CH₃)═CH₂]RuC₅H₄CH₂[N(CH₃)₂]

In a contemplated embodiment, M=Ru, R₁═H and R₂═CH(OH)R₃ and R₃═CH₃ or C₂H₅. The choice of these groups provide for an optimal ruthenium precursor suitable for atomic layer deposition. Additionally, combinations of the R groups and other metals as presented above provide flexibility for these precursors to be used in the other chemical vapor deposition techniques defined above.

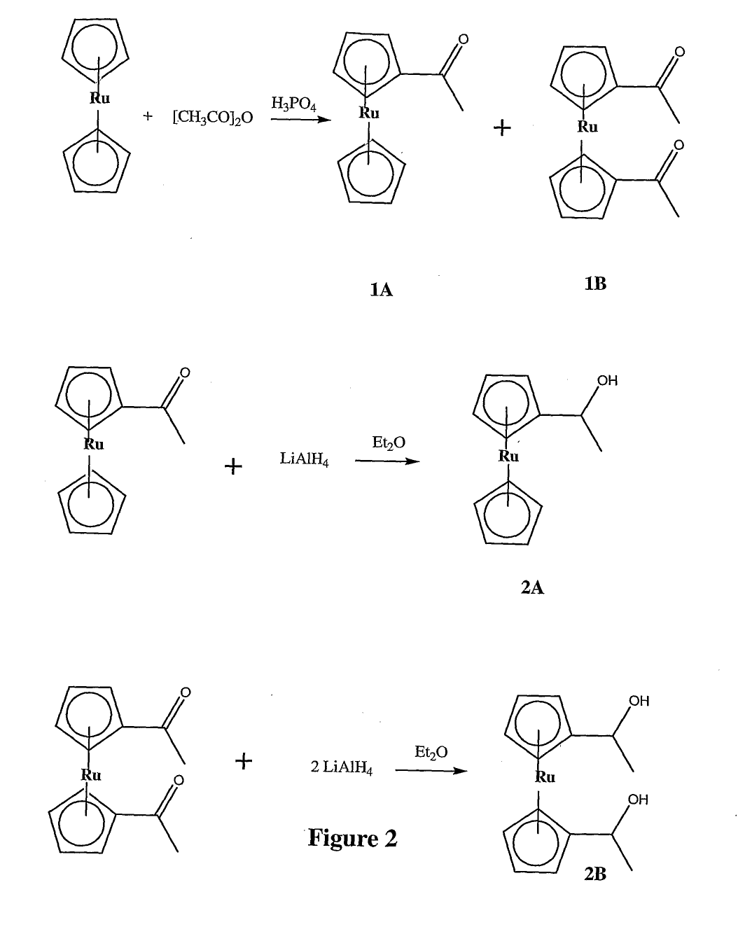

The synthesis of contemplated organometallic compounds in certain embodiments is illustrated in FIG. 2. The starting material, bis(cyclopentadienyl)ruthenium, known as ruthenocene is commercially available and can be prepared according to methods described by Bublitz, D., McEwen, W., and Kleinberg, J., Organic Synthesis, 5, 1001 (1973) and Holt, Smith L. (editor), Inorganic Synthesis, 22 (1983), which are both incorporated herein by reference. The reaction of ruthenocene with acetic anhydride to form 1-acetylruthenocene (1A) in presence of aluminum chloride as Friedel-Crafts catalyst has also been disclosed by Hill et al. in the Journal of the American Chemical Society, Vol. 83, pages 3840-3846 (1961) which is hereby incorporated by reference. Use of aluminum chloride catalyst always resulted in the formation of both mono and di-substituted compounds (1A & 1B), which had to be subsequently separated by column chromatography using benzene-ether solvent mixture. Benzene is a known carcinogenic material and its use on a large scale is hazardous and unwarranted.

To produce large quantities of 1-acetylruthenocene as an intermediate that can lead to the formation of a final ALD precursor product, 1-hydroxyethylruthenocene (2A, R₁═CH₃), an improved synthesis of the acylated compound was developed. We discover that the treatment of ruthenocene with acetic anhydride using phosphoric acid as the Friedel-Crafts catalyst produces the desired mono-acylated product (1A) with much higher yield than the prior arts. In a typical reaction, ruthenocene is reacted with acetic anhydride in the presence of a phosphoric acid catalyst. The amount of acetic anhydride is generally not critical, but a sufficient amount should be added as this compound also serves as reaction solvent. The amount of acetic anhydride used for this synthesis can vary from 2-10 moles per mole of ruthenocene used in the reaction. In some embodiments, the moles of anhydride used per mole of ruthenocene are 3-8. In other embodiments, the molar amount of anhydride is 4-6 moles based on a mole of ruthenocene used in the preparation.

The amount of phosphoric acid catalyst utilized in the synthesis can range from about 0.01 moles to 1 mole based on a per mole equivalent of ruthenocene. To accelerate the reaction, it is contemplated that the range of phosphoric acid, which should be utilized on a per mole basis of ruthenocene used in the reaction, is about 0.3 to 0.5 moles. Using this ratio, the reaction can be completed in as little as 3 h with yields exceeding 90%. The reaction temperature utilized in the synthesis can vary from about 15-95° C. In some embodiments, the reaction temperature is about 40-60° C. Maintaining this temperature minimizes the amount of formation of the di-substituted acylated product (1B). Substitution of acetic anhydride with higher homologues such as propionic anhydride gives corresponding acylated metallocenes.

In the preparation of 1-hydroxyethylruthenocene, the acylated product, 1A (R₁═CH₃) prepared as described above, is reduced with lithium aluminum hydride (LAH), in ether solvent, to give good yields of 1-hydroxyethylruthenocene (2A, R₁═CH₃), which is a solid with a melting point of about 53-55° C. Reduction can also be carried out using sodium borohydride or derivatives of sodium borohydride in ether. The amount of reducing agent required for the reaction on a mole basis as referenced to 1 mole of acylated metallocene can vary from about 0.25 up to 2.0 moles. A contemplated mole ratio is about 0.25 to 1. Another contemplated range is about 0.3 to 0.5 moles as this amount converts the acylated metallocene quantitatively to the desired product. Ethers such as diethyl, di n-propyl, di n-butyl ethers, glymes and cyclic ethers such as tetrahydrofuran (THF) and 1,4-dioxane can be used as a reaction solvent to carry out the reduction. The amount of ether used in the synthesis is generally not critical as it is the reaction solvent and inert. A contemplated reaction temperature can range from about 15-33° C., and in some embodiments, the reaction temperature can range from about 30-33° C.

For the di-acylated product, which was obtained from the aluminum chloride catalyzed reaction, the amount of reducing agent required is essentially doubled in comparison to the quantities described above. To convert the di-acylated product to the di-alcohol, 2B, the amount of LAH can range from about 0.5 to 4 moles. In some embodiments, the amount of LAH can range from about 0.5 to 2 moles, and in other embodiments, the amount of LAH can range from about 0.6 to 1 mole.

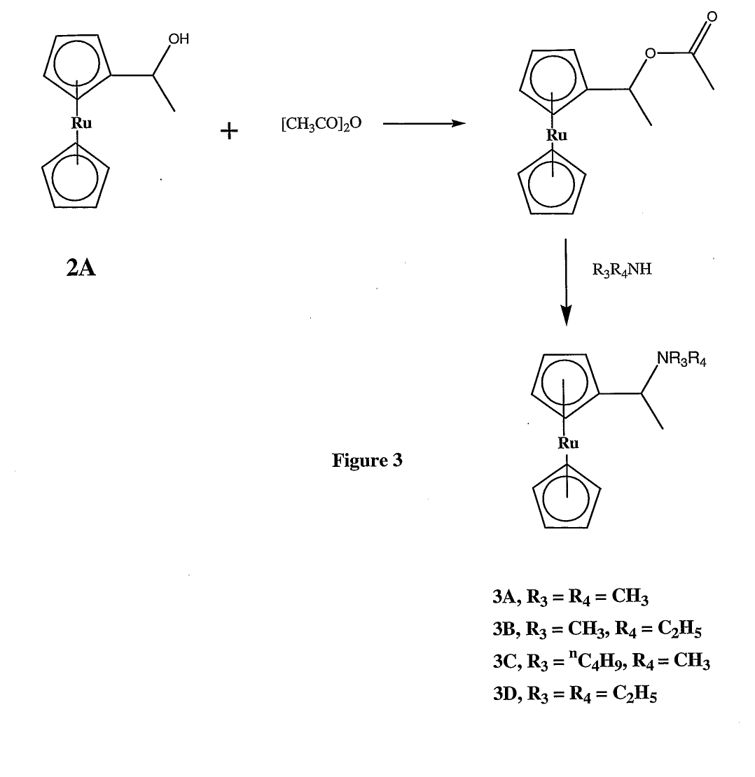

In another contemplated embodiment, M=Ru, R₁═H and R₂═CH(CH₃)(NR₄R₅) where R₄ and R₅ are the same or different and comprise CH₃, C₂H₅, C₃H₇ and ⁿC₄H₉. The choice of these groups provide for an optimal volatile ruthenium precursor suitable for atomic layer deposition. Additionally, combinations of the R groups and other metals, as presented above, provide added flexibility for these precursors to be synthesized and used in the chemical vapor deposition techniques mentioned above. The synthesis of the organometallic compounds contemplated herein is illustrated in FIG. 3.

Synthesis of 1-hydroxyethylruthenocene was described in U.S. Provisional Application Ser. No. 60/740,172 filed Nov. 28, 2005 entitled “Ruthenium Precursors and Their Intermediates for Deposition, Their Production and Method of Use”, which is commonly-owned and incorporated herein by reference. In the preparation of [1-(dimethylamino)ethyl]ruthenocene (3A, R₃═R₄═CH₃), the first step is reaction of 1-hydroxyethylruthenocene with acetic anhydride to give the intermediate acetate. This acetate is subsequently reacted with a secondary amine of choice (such as dimethylamine) using anhydrous or aqueous alcohol as solvent to give [1-(dimethylamino)ethyl]ruthenocene as a solid with a melting point of 60-61° C. The selection of the alcohol is not critical and is chosen from methanol, ethanol or isopropanol. These alcohols are chosen based on the solubility of the starting alcohol and the amine in them, as well as their ease of removal when the reaction is completed. The mole ratio of amine to alcohol is also not critical and can range from 1:1 to 10:1, and in some embodiments, the mole ratio is 5:1 to 8:1.

The temperature of the reaction can range from ambient up to the reflux temperature of the corresponding alcohol used as reaction solvent. In contemplated embodiments, the reaction temperature is at or near ambient temperature. Replacement of dimethyl with ethylmethyl amine as the secondary amine in the above reaction sequence gives the corresponding [1-(ethylmethylamino)ethyl)ruthenocene (3B, R₃═CH₃, R₄═C₂H₅), as a liquid with a boiling point of 106-7° C. @ 0.002 torr. Similarly, use of methylbutyl and diethyl amine as secondary amines give the corresponding [1-(ⁿbutylmethylamino)ethyl]ruthenocene (3C, R₃=ⁿC₄-1H₉, R₄═CH₃) and [1-(diethylamino)ethyl]ruthenocene (3D, R₃═R₄═C₂H₅) as liquids with boiling points of 118-122° C. @ 0.005 torr and 104-107° C. @ 0.005 torr, respectively in high yields.

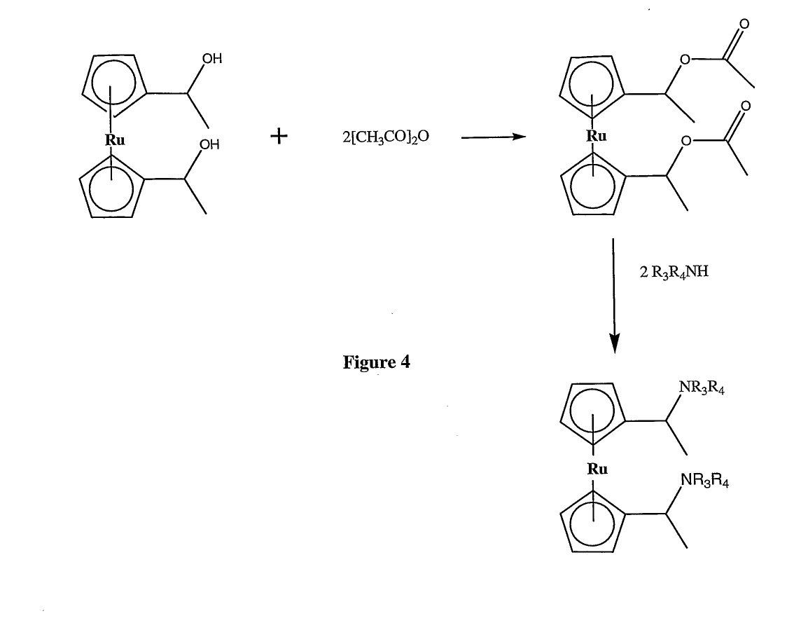

In a contemplated synthesis of the substituted ruthenocene, where R₁═R₂, the ruthenocene can be prepared by treating the symmetrically substituted bis(acetate) with the amine of choice as depicted in FIG. 4.

In another contemplated embodiment, M=Ru, R₁═H and R₂═CH₂(NR₄R₅) where R₄ and R₅ are the same or different and comprise of CH₃, C₂H₅ and ⁿC₄H₉. The choice of these substituents provide for an optimal volatile ruthenium precursor suitable for atomic layer deposition. These compounds can be prepared in one step from bis(cyclopentadienyl)ruthenium, (Cp)₂Ru. For example, treatment of bis(cyclopentadienyl)ruthenium with bis(dimethylamino)methane in acetic acid in presence of phosphoric acid catalyst gave [(dimethylamino)methyl]ruthenocene as a yellow solid (melting point 39-41° C.) in 80% yield.

### Atomic Layer Deposition Apparatus and Methods

The compounds and compositions described herein may be used in at least one vapor deposition process, including ALD, PEALD, LI-ALD (Liquid Injection ALD), LI-PEALD, CVD, LI-CVD, MOCVD, AVD, etc. These deposition processes are well-known and their general apparatus and parameters should be understood by those of ordinary skill in the art. By using the Ru precursors described herein in combination with the ALD processes discovered, significant Ru ALD film performance improvements such as growth rate, conductivity, and purity can be simultaneously realized. This will be described in more details herein and illustrated through the Examples. The film crystallinity and crystal orientation was measured by X-ray diffraction and the film surface roughness (RMS) was measured by AFM (Atomic Force Microscopy). The film sheet resistance was measured by four-point probe and the film resistivity was calculated as film sheet resistance multiplied by film thickness with the product divided by 10.

Film sheet resistance is reported in ohm, film thickness is nm, and film resistivity is μohm-cm. The film adhesion was evaluated by peel-off test using 3M scotch tape on 0.5 cm² film surface area. The film thickness was measured by cross sectional SEM (Scanning Electron Microscopy), RBS (Rutherford Backscattering Spectroscopy), XRR (X-Ray Reflectivity) and EDX (Energy Dispersive X-ray).

Metallic precursor compounds, as shown in FIG. 1, particularly where M=Ru, can be utilized in the atomic layer deposition process. As previously mentioned, ALD is a thin film deposition process in which a chemical reaction between a metallic precursor and a reactant in the gas phase occurs on the surface of a substrate. In ALD, the vapors of the source materials are introduced into the reactor alternately, one at a time and separated by purging with an inert gas or by evacuation. Each exposure of precursor saturates the surface with a monomolecular layer of that precursor. This results in a self-limiting growth mechanism that facilitates growth of uniform, conformal thin films with accurate film thickness over large areas. The above sequence is repeated until the desired thickness of metal or metal oxide film is achieved on the substrate. The final thickness is determined by the film growth rate per cycle and the total number of cycles applied in the deposition process, and the film thicknesses can range from less than a nanometer to a few microns, depending on the applications. In general, the exposure time is variable and can range from less than a second to up to a few minutes, the limiting time being dependent on the substrate surface and specification of the ALD instrument.

Methods of vaporizing the metallic precursors having the formula shown above comprise heating the precursor to a particular temperature and exposing a surface of the substrate to the vapor to form a film. This vaporization step may be performed by any suitable method. Contemplated deposition apparatus and methods are described in more detail herein

### Thermal Atomic Layer Deposition

Thermal atomic layer deposition can be used with the contemplated vaporizable precursors and compounds described herein to deposit Ru films. According to typical ALD methods, a substrate is placed in a reaction chamber and the chamber is pumped down to 10⁻⁷-10⁻⁸ Torr and back filled with inert gas while keeping the pressure at about 0.1 Torr to a few Torr. The substrate is heated up to suitable deposition temperature typically in the range of 200-500° C. at lowered pressure and a metallic precursor compound is pulsed into the reaction chamber in the gaseous phase and chemisorb on the substrate surface with about one monolayer of the compound adsorbed onto the surface. After the precursor pulse step, the excess of the metallic precursor compound is purged out of the reaction chamber using an inert gas in combination with vacuum pump down. Subsequently, a second reactant is pulsed onto the substrate to react with the metallic precursor materials adsorbed on the surface in the previous step. Then, the excess of the second reactant and the gaseous by-products of the surface reactions are purged out of the reaction chamber.

The steps of pulsing and purging are repeated in the indicated order until the desired thickness of the depositing thin film is reached. The method is based on controlled surface reactions of the precursor chemicals. Gas phase CVD reactions are avoided by feeding reactants alternately into the reaction chamber. Vapor phase reactants are separated from each other in the reaction chamber by removing excess reactants and/or reactant by-products from the reaction chamber, such as with an evacuation step and/or with an inactive gas pulse (e.g. nitrogen or argon).

Metallic precursor compounds contemplated herein comprise neutral organometallic compounds and are either liquids or solids at room temperature and that melt at or below 100° C. These complexes are suitable for use in vapor deposition techniques such as CVD, MOCVD, thermal ALD and PEALD. Examples of ruthenium-containing vaporizable precursor compounds include, but not limited to: 1-hydroxyethylruthenocene, [1-(dimethylamino)ethyl]ruthenocene, [1-(ethylmethylamino)ethyl]ruthenocene, [1-(ⁿbutylmethylamino)ethyl]ruthenocene, [1-(diethylamino)ethyl]ruthenocene, [1-(isopropylmethylamino)ethyl]ruthenocene, [1-(methylpropylamino)ethyl]ruthenocene, [1-(ethylisopropylamino)ethyl]ruthenocene, [1-(ⁿ(butylpropylamino)ethyl]ruthenocene, [1-(diⁿpropylamino)ethyl]ruthenocene, [1-(diisopropylamino)ethyl]ruthenocene, [1-(cyclohexylmethylamino)ethyl]ruthenocene, [(dimethylamino)methyl]ruthenocene, [(ethylmethylamino)methyl]ruthenocene, [(ⁿbutylmethylamino)methyl]ruthenocene, [(diethylamino)methyl]ruthenocene or combinations thereof. In some embodiments, contemplated ruthenium complexes comprise: 1-hydroxyethylruthenocene, [1-(dimethylamino)ethyl]ruthenocene, [1-(ethylmethylamino)ethyl]ruthenocene, [1-(ⁿ(butylmethylamino)ethyl]ruthenocene, [1-(diethylamino)ethyl]ruthenocene or [(dimethylamino)methyl]ruthenocene.

[1-(ethylmethylamino)ethyl]ruthenocene, [1-(ⁿ(butylmethylamino)ethyl]ruthenocene and [1-(diethylamino)ethyl]ruthenocene are liquids at room temperature, and 1-hydroxyethylruthenocene, [1-(dimethylamino)ethyl]ruthenocene and [(dimethylamino)methyl]ruthenocene are solids at room temperature that melt between 35 and 65° C.

As described herein, the second reactant can be either an oxidizing or a reducing material. Suitable oxidizing materials include but not limited to are air, oxygen, ozone, nitrous oxide (N₂O), nitric oxide (NO), nitrogen dioxide (NO₂), nitrogen pentoxide (N₂O₅), hydrogen peroxide (H₂O₂), derivatives thereof and combinations thereof.

Examples of reducing materials comprise hydrogen, atomic hydrogen, ammonia, silane, polysilanes, alkylsilanes, arylsilanes, halosilanes, borane, diborane, polyboranes, alkylboranes, derivatives thereof and combinations thereof. Polysilanes include mono, di-, tri- and tetrasilanes. Examples of alkylsilanes are methyl, ethyl and propylsilanes, examples of aryl silanes are phenyl silane, diphenylsilane and derivatives thereof and examples of halosilanes are chloro, bromo, fluoro and iodosilanes. Polyboranes include triborane, tetraborane and pentaborane and examples of alkylboranes are methyl, ethyl, propyl and butylboranes. In some contemplated embodiments, non-metallic reactants are air, oxygen, silane and diborane and are gases at room temperature.

A substrate surface as described herein refers to any substrate or material surface formed on a substrate upon which film processing is performed. Examples of substrate surface include but not limited to crystalline or amorphous silicon, silicon oxide, silicon dioxide, silicon nitride, silicon oxynitrides and soda lime glass. Additionally, the substrate has a film or seed layer either deposited via a vapor deposition method, patterned or by any suitable means on its surface. Methods of vapor deposition to deposit a seed layer onto the substrate include physical vapor deposition, chemical vapor deposition or atomic layer deposition. Examples of seed layer are: tantalum nitride, titanium nitride, tungsten nitride, tungsten carbonitride, titanium aluminum nitride, ruthenium, iridium, platinum, tungsten, copper, aluminum, nickel, titanium silicides or dielectric materials such as aluminum oxide, hafnium oxide, zirconium oxide, tantalum oxide, titanium oxide, hafnium silicate, strontium titanate, and barium strontium titanate. Substrates may have various dimensions such as 100 mm, 200 mm or 300 mm diameter wafers as well as circular, rectangular or square wafers. The substrate surface can be flat, round, trenched or other patterned.

In some embodiments, the substrate can be of any shape and form with exposed surface so that the precursor gas can adsorb on the surface to form a film or coating. The substrate can have a 2-D or 3-D structure and may be a powder.

Before starting the deposition of the film, the substrate is typically heated up to a suitable growth temperature. In some embodiments, the growth temperature of metal thin film is approximately from about 200 to 500° C., and in other embodiments from about 250 to 450° C. for ruthenium. For some contemplated precursors described herein, the temperature can go up to about 500° C.

Metallic precursor compound is vaporized in the source and delivered onto the substrate surface. A contemplated source temperature is in the range of about 0° C. to about 300° C., and in other embodiments the range is room temperature to about 175° C., depending on the reactants' vapor pressure and thermal stability. The precursor supply can take place with or without a carrier gas such as nitrogen, argon and hydrogen. Other example of metallic precursor delivery includes dissolving the precursor into a predetermined liquid organic solvent to give a liquid solution, and then delivering the solution to a vaporizer where it is vaporized and the vapor is delivered to the substrate surface with or without the carrier gas.

In the vaporizable compounds pulse step, one or several different metal-based vaporizable precursor compounds can be used depending on the structural and composition requirement on the thin films. Such introduction of different metal-based vaporizable precursors will result into the formation of doped, alloyed or nanolaminated thin films. Different metal-based vaporizable precursors can also be co-pulsed into and adsorbed onto the substrate surface for doped or alloyed thin film formation. The alloyed thin films include, but not limited to Ru—Pt. The nanolaminated thin films include, but not limited to Ru—TaN and Ru—Cu.

The processing time depends on the thickness of the layer to be produced and the growth rate of the film. In ALD, the growth rate of a thin film is determined as thickness increase per one cycle. One cycle consists of the pulsing and purging steps of the precursors and the duration of one cycle and may range from 0.1 second to about 100 seconds. The cycle time is dependent on the ALD system used in depositing the film and should be short from production standpoint. ALD equipment having a small open space in the reaction chamber, and gas supply and exhaust systems to maximize the flux of the incoming and outgoing gases, would have short cycle time.

Examples of suitable arrangements of reactors used for the deposition of thin films are any commercially available ALD equipment, for example the F-120, F-120 SAT and PULSAR™ reactors produced by ASM Microchemistry Ltd, and the STRATAGEM™ made by Aixtron-Genus. In addition to these ALD reactors, many other kinds of reactors capable for ALD growth of thin films, including CVD reactors equipped with appropriate equipment and means for pulsing the precursors can be utilized. The growth processes can be carried out in a cluster tool, where the substrate arrives from a previous process step, the metal film is produced on the substrate, and then the substrate is transported to the following process step. In a cluster tool, the temperature of the reaction space can be kept constant, which clearly improves the throughput compared to a reactor in which the substrate is heated up to the process temperature before each run.

A contemplated process for depositing thin films by vapor deposition, comprises: a) providing the metalorganic precursor compound comprising at least one metal with a donor group substituted ligand represented in FIG. 1, b) vaporizing the compound to form vapors of that compound, c) providing a reactant(s), and d) reacting the reactant(s) with the vaporized metalorganic precursor compound to form a thin film on the substrate surfaces.

Deposition of thin films can include, without limitation, chemical and other mechanisms. Typical chemical mechanisms include oxidation to form oxide and reduction to form metal and combinations thereof.

In one embodiment, the resulting product is a dense uniform conformal coating on a surface. In another embodiment, at least one vaporizable compound is patterned on a surface through selective area ALD. In yet another embodiment, the deposited film is subject to further processing such as annealing, multilayer deposition of different materials, or selective etching. In yet another embodiment, deposited film thickness is a uniform thickness within about 1 nm to about 1 μm.

In a contemplated embodiment, a mixture of vaporizable precursor compounds is used. In another embodiment, different vaporizable compounds are used in adjacent cycles to make interlayers.

The metal films obtained from thermal ALD process, such as ruthenium films described in the following examples, have high purity, high density and low resistivity (high electrical conductivity). Such ruthenium films with good conformity from the metal organic precursor compound will be advantageous for barrier/copper seed application of chip interconnect, gate stack electrode and capacitor electrode. Some other embodiments include multilayer films and coated powders made in a fluidized bed.

### Plasma-Enhanced Atomic Layer Deposition

The thermal ALD of ruthenium precursors described herein are most suitable for depositing a ruthenium film on an oxidation resistant surface such as an oxide. The process of forming a ruthenium thin film prepared by thermal ALD using oxygen or air as a co-reactant may oxidize the under-layered metal or metal nitride and form an interfacial metal oxide film. Such oxide formation increases the total electrical resistance of the metal or metal nitride layer and may cause device failure. Furthermore, thermal ALD processes using conventional ruthenium precursors is known to have a incubation period at the beginning of ruthenium film growth, resulting in non-continuous ruthenium film when the thickness is less than about 5 nm.

To solve the above problems, we have discovered a plasma enhanced atomic layer deposition (PEALD) process using reducing gases that do not oxidize metal or metal nitride. Advantageously, the PEALD of the ruthenium precursors described herein yields pure, dense, smooth, and highly conductive ruthenium films with higher growth rate. Surprisingly, the incubation period for the Ru film made by the process and precursor described herein is low, such that the Ru film formed is continuous and conductive at a thickness less than about 5 nm.

PEALD data and information as it relates to the subject matter provided herein can be found in U.S. Provisional Application Ser. No. 60/740,206 filed on Nov. 28, 2005, which is entitled “Ruthenium Precursors and Intermediates for Plasma-Enhanced ALD” and which is commonly-owned and incorporated herein by reference in its entirety.

For example, methods of depositing the ALD precursor in PEALD can comprise the following preparation steps:
1. Place a substrate in a chamber whereby the chamber is evacuated to reduce the level of water to <about 50 ppm and the level of oxygen to <about 100 ppm;
2. The work piece is then placed in the chamber via a loadlock evacuated to reduce the level of water to <about 50 ppm and the level of oxygen to <about 100 ppm so as to prevent exposing the chamber to normal room air;
3. The work piece is placed on a surface heated to a temperature from about 200° C. to about 400° C.;
4. The chamber is purged with an inert gas comprising argon, helium, nitrogen, krypton, and mixtures thereof;
5. The metallic precursor, such as those described herein, is entrained in a carrier gas comprising argon, helium, nitrogen, krypton, and mixtures thereof;
   wherein the precursor makes up at least about 1.0 volume % of the entrained carrier gas, wherein the flow rate of the gas is about 0.1 sccm to about 100 sccm, wherein the carrier gas temperature is about 20° C. to about 170° C.,
   wherein the carrier gas line may be heat traced, wherein the chamber walls are heated to temperatures from about 20° C. to 180° C.; and
   wherein the diameter of the carrier gas line is at least about 6 mm; and
6. Entering the entrained carrier gas into the chamber at a distance of about 1 cm to about 20 cm from the substrate, wherein the angle of entry can be about 0° C. to about 90° C. if the entrained gas at least partially directly impinges the substrate.

In addition, methods of depositing the vaporized metallic precursor in PEALD comprise the following steps, which can be repeated:
1. Enter purge gas from the group consisting of inert gases, argon, helium, nitrogen, krypton, and mixtures thereof wherein the flow rate of the gas is about 10 sccm to about 100 sccm, for a time of gas entry from 0.1 seconds to 50 seconds;
2. Enter entrained precursor gas mixed with a carrier gas comprising argon, helium, nitrogen, krypton, and mixtures thereof at a temperature in the range from about 200° C. to about 400° C. for time of about 0.1 seconds to about 50 seconds, sufficient to cause adsorption of the precursor such that the metal binds or lays on the substrate and at least 5 wt % of the ligand is removed from the substrate;
3. Enter purge gas from the group consisting of inert gases, argon, helium, nitrogen, krypton, and mixtures thereof wherein the flow rate of the gas is about 10 sccm to about 100 sccm, for a time of gas entry from about 0.1 seconds to about 50 seconds;
4. Enter non-metallic co-reactant gas which comprises nitrogen, ammonia, nitrous oxide, hydrazine, hydrogen, oxygen, ozone, and mixtures thereof wherein the flow rate of the gas is about 10 sccm to about 100 sccm, for a time of gas entry from about 0.1 seconds to about 50 seconds;
5. Turn on plasma at 0.05 to 3 W/cm² at a frequency between 0 and 200 kHz, where the electrode configuration is preferable a parallel-plate capacitive structure with a spacing of about 2 to 20 cm;
6. Enter purge gas which comprises inert gases, argon, helium, nitrogen, krypton, and mixtures thereof wherein the flow rate of the gas is about 10 sccm to about 100 sccm, for a time of gas entry from 0.1 seconds to 50 seconds;
7. Repeat steps 1-6 above for 1 to 3000 times; and
8. Residual gases are pumped from the system to a total pressure of less than 0.1 torr prior to removal of the sample.
9. In some embodiments, an optional post treatment will follow the deposition steps.

It should be understood that in the above-described processes, the precursor is heated to a predetermined source temperature without significant thermal decomposition of the precursor. In some embodiments, the source temperature for the precursors is kept between about 60 to 150° C. In some embodiments, the precursor can be dissolved in an organic solvent and then vaporized with the precursor, which is commonly referred to as liquid injection ALD.

Ruthenium films having a ruthenium content of greater than about 95% can be deposited at a growth rate of about 0.02 to about 0.3 nanometers for each deposition cycle using NH₃ or N₂ as the reactants. For these deposition cycles, it is recommended that the plasma power be between about 50 and 500 Watts and that the wafer/substrate temperature be between about 200 and 400° C. In some embodiments, the precursor pulse time is from about 0.5 to about 50 seconds. In addition, by increasing the exposure time of the oxygen or ozone reactants to between about 5 and 50 seconds, contemplated ruthenium films may comprise between about 0 and 67 atomic percent of oxygen. In a contemplated embodiment, the root-mean-square (RMS) roughness of the ruthenium film can be measured at less than 1.0 nm for a film with a thickness from about 5 to 50 nm by using the processes described above wherein the plasma power is about between 50 and 300 Watts, the wafer/substrate temperature is about 200-400° C. and the precursor pulse time is between 0.5 and 50 seconds.

In these methods, the wafer/substrate is alternatively exposed to vaporizable ruthenium precursor and H₂, O₂, NH₃, N₂O or N₂ plasma or their mixture at substrate temperatures of 100-400° C., and source (ruthenium precursor) temperatures of 60-200° C. and a reactor pressure of about 1 Torr. The ALD cycle in this method consists of exposure of the ruthenium precursor, reactor purge with the inert gas, reactant plasma gas exposure and reactor purge again with the inert gas. This cycle is repeated as many times as it is necessary to obtain the desired film thickness. In another embodiment, the plasma is pulsed while the gases and vapors are constant or varied less than in usual ALD to reduce the number of steps or time in a cycle. For example, the at least part of the purge gas can be used as a reactant upon activation by the plasma.

Suitable vaporizable ruthenium precursor compounds contemplated herein are neutral organometallic compounds and are either liquids or solids at room temperature that melts at or below 100° C. Examples of ruthenium-containing vaporizable precursor compounds include, but not limited to 1-hydroxyethylruthenocene, [1-(dimethylamino)ethyl]ruthenocene, [1-(ethylmethylamino)ethyl]ruthenocene, [1-(ⁿbutylmethylamino)ethyl]ruthenocene, [1-(diethylamino)ethyl]ruthenocene, [1-(isopropylmethylamino)ethyl]ruthenocene, [1-(methylpropylamino)ethyl]ruthenocene, [1-(ethylisopropylamino)ethyl]ruthenocene, [1-(ⁿbutylpropylamino)ethyl]ruthenocene, [1-(diⁿpropylamino)ethyl]ruthenocene, [1-(diisopropylamino)ethyl]ruthenocene, [1-(cyclohexylmethylamino)ethyl]ruthenocene, [(dimethylamino)methyl]ruthenocene, [(ethylmethylamino)methyl]ruthenocene, [(ⁿbutylmethylamino)methyl]ruthenocene and [(diethylamino)methyl]ruthenocene. In some embodiments, contemplated ruthenium complexes comprise 1-hydroxyethylruthenocene, [1-(dimethylamino)ethyl]ruthenocene, [1-(ethylmethylamino)ethyl]ruthenocene, [1-(ⁿbutylmethylamino)ethyl]ruthenocene, [1-(diethylamino)ethyl]ruthenocene and [(dimethylamino)methyl]ruthenocene.

[1-(ethylmethylamino)ethyl]ruthenocene, [1-(ⁿbutylmethylamino)ethyl]ruthenocene and [1-(diethylamino)ethyl]ruthenocene are liquids at room temperature, and 1-hydroxyethylruthenocene, [1-(dimethylamino)ethyl]ruthenocene and [(dimethylamino)methyl]ruthenocene are solids at room temperature that melt between 35 and 65° C.

PEALD can be carried out on a metal, metal oxide, metal nitride or metal carbide substrate to deposit the ruthenium metal films. In the manufacturing of semiconductor devices, PEALD of ruthenium can be carried out on substrates such as SiO₂, Al₂O₃ coated SiO₂/Si, rare earth oxides, rare earth aluminates, HfSiO, HfSiON, HfO₂, ZrSiO, ZrSiON, ZrO₂, Ta₂O₅, TiO₂, strontium titanate, barium strontium titanate (BST), TaN, TiN, WN, WNC, MoN, HfN, ZrN, Ta, Mo, and patterned Si, low K dielectrics or high K dielectric substrates to deposit the ruthenium metal film. The resultant structures containing the PEALD ruthenium film of this example are most suitable for the advanced capacitor, metal gate stack, interconnect liner, and local contact plug applications. It may also be applied to the manufacturing of the capping layer in EUV lithography and in the copper interconnect for reducing copper electromigration.

In some embodiments, an ALD/CVD hybrid method can be performed wherein the purge gas steps, as outlined above, are reduced in time to less than about 25 seconds, which results in incomplete separation of the reactants and increased growth rate. The resulting ruthenium films will have growth rates of greater than about 0.1 nm per cycle, especially when utilizing plasma powers of about 50-500 Watts and a substrate/wafer temperature of about 200-400° C. In other embodiments, the organometallic precursors disclosed herein can be deposited by eliminating the purge gas steps. In these embodiments, the cycled nature of the deposition is achieved by cycling the plasma power without the purging step for reactant gas. In another embodiment, the plasma gases may be generated remotely and brought into the ALD chamber externally.

### Resulting Films & Other Applications and Uses

The disclosure herein relates to the synthesis and production of novel precursors and their uses in ALD processes described above that result in a conducting film of superior properties needed by the semiconductor industry. For example, ruthenium films formed by the methods and precursors disclosed herein can have thicknesses of less than about 10 nm with an average resistivity below 30 μΩ-cm. Unexpectedly, the product described herein has a growth rates >0.06 nm/cycle in the incubation period when the number of cycles is about 100 or less.

A person of ordinary skill in the art should now understand how the parameters can be combined thereby maximizing performance of the apparatus and quality of the film. A wide variety of vaporizable organometallic precursors can be utilized with these processes depending on the combination of parameters utilized.

The applications and uses of these precursors and resulting films are as follows: a) ruthenium or ruthenium oxide electrodes for the DRAM MIM capacitor structure with silicon substrates of 5-50 nm film thickness per layer, b) ruthenium metal for high κ gate metal for gate stack in CMOS logic of 1-10 nm film thickness, c) ruthenium metal interconnect for diffusion barrier used as a bonding promoter for copper and seed layers in copper plating of 1-20 nm film thickness, d) ruthenium electrodes of 5-50 nm thickness for FRAM and MRAM applications, and e) ruthenium metal channel layer for MRAM of about 1 nm.

In one of the embodiments, the PEALD ruthenium film has a strong preference to exhibit (002) crystal orientation, particularly after an annealing at temperature between 450 and 750° C. in inert or reducing atmosphere. The annealing results in the reduction of resistivity by at least 10%. The (002) orientation of Ru enhances the bonding between copper and ruthenium in the interconnect application, and growth of high κ oxides of tantalum, zirconium and titanium with contemplated crystal orientation of higher dielectric constants.

The advantages of using the precursors of the application should now be apparent. The compounds described herein serve as novel precursors for use in chemical vapor deposition techniques, particularly atomic layer deposition. The ability to functionalize the cyclopentadienyl ring allows for the tailoring of properties to suit the chemistry of the substrate being utilized in the deposition process. It is possible to modify such properties as solubility, vapor pressure, reaction pathways, thermal stability and reduction/oxidation potentials in order to provide an optimized metallocene for a specific application.

### EXAMPLES

In order that the description herein may be more readily understood, reference is made to the following examples that are intended to be illustrative, but are not intended to be limiting in scope.

### Example 1

### Synthesis of (1-Acetyl)Ruthenocene

Ruthenocene (146.59 g, 0.6336 mol) was added to a flask containing acetic anhydride (408 g, 4 mol). Phosphoric acid (37 g, 0.37 mol) was then added drop-wise at a rate to maintain the internal temperature at or less than 40° C. Upon completion of addition, the reaction temperature was raised to 60° C. and maintained at that temperature for 4 hours with stirring. Afterwards, the reaction mixture was cooled to 10° C., hydrolyzed with 300 mL of water and stirred for an additional 2 hours. The resulting solid was filtered, washed with water (2×500 mL) and then vacuum dried at 45° C. for 6 hours to give 162.6 g of 1-acetylruthenocene for 93.9% isolated yield. The ¹H NMR spectrum indicates presence of monoacylated product as the sole compound and di-acylated material was not detected in the spectrum.

### Example 2

### Synthesis of (1-Hydroxyethyl)Ruthenocene (2A)

Into an ethereal solution of lithium aluminum hydride (LAH) prepared by dissolving 5.46 g LAH (0.144 mol) in 1 L of ether, 78.31 g of 1-acetylruthenocene (0.28 mol) was added slowly to maintain the internal reaction temperature between 15-20° C. Upon completion of addition, the reaction mixture was refluxed for 2.5 hours and unreacted LAH was quenched by treating the reaction mixture sequentially with 5 mL water, 5 mL 15% aqueous NaOH solution and 15 mL water followed by stirring for 1 hour. It was filtered to remove aluminum salts and the filtrate was evaporated to dryness to yield crude product as a yellow solid (71 g, 89.9% yield). Recrystallization of the crude material with n-heptane gave analytically pure sample in 75% yield. The ¹H NMR spectrum was consistent with structure of 1-hydroxyethylruthenocene, 2A and unreacted starting material was not detected in the spectrum. Elemental analysis: calculated for C₁₂H₁₄ORu: C, 52.35%; H, 5.13%; Ru, 36.76%. found: C, 52.74%; H, 5.29%; and Ru, 36.3%.

### Example 3

### Synthesis of (1-Propinoyl)Ruthenocene

This material was prepared as described in Example 1, except propionic anhydride, (CH₃CH₂CO)₂O was used.

### Example 4

### Synthesis of (1-Hydroxypropyl)Ruthenocene

This compound was prepared as described in Example 2, except that the acyl-metallocene used in the synthesis was derived from Example 3.

### Example 5

### Synthesis of (1-Butyryl)Ruthenocene

This compound was prepared as described in Example 1, except butyric anhydride was used instead.

### Example 6

### Synthesis of (1-Hydroxybutyl)Ruthenocene

This compound was prepared as described in Example 2, except that the acyl-metallocene used in the synthesis was derived from Example 5.

### Example 7

### Synthesis of (1,1′-Diacetyl)Ruthenocene

This compound was obtained by following the procedure of Hall as referenced in the text of this application. The product was isolated by column chromatography in 12% yield.

### Example 8

### Synthesis of [1,1′-Bis(Hydroxyethyl)]Ruthenocene

This compound was prepared as described in Example 2, except that the quantity of LAH used was doubled.

### Example 9

### Synthesis of 1-Ruthenocenylacetate

Into a solution of 1-hydroxyethylruthenocene (61.8 g, 0.224 mol) dissolved in 350 mL of methylene chloride kept under nitrogen atmosphere were added triethylamine (40.8 mL, 0.29 mol) and 5 mol % 4-(dimethylamino)pyridine. The reaction mixture was cooled to about 0-2° C., at which point acetic anhydride (25.2 mL, 0.27 mol) was added at a rate to maintain the internal reaction temperature below 5° C. The mixture was then allowed to warm to ambient temperature and stirred for 25 h. Water (50 mL) was added and the resultant mixture was phase separated. The organic layer was dried over MgSO₄ and concentrated under reduced pressure to yield an oily product that solidified upon standing. The yield of the intermediate acetate was 71 g (quantitative) and ¹H NMR was consistent with the proposed structure. ¹H NMR (CDCl₃): δ 1.43 (d, 3H), 2.02 (s, 3H), 4.51-4.67 (m, 4H), 4.52 (s, 5H), 5.62 (q, 1H)

### Example 10

### Synthesis of [1-(Ethylmethylamino)Ethyl]Ruthenocene (3B)

The acetate prepared in Example 9 (6 g, 0.0188 mol) was dissolved in ethanol (50 mL) and to this solution was added ethylmethylamine (9.91 g, 0.168 mol) as a 50 vol % water solution. After stirring the reaction mixture for 72 h, the solvent was removed under reduced pressure and the resultant residue was dissolved in 50 mL ether. The ruthenocenyl amine was extracted with 20 mL of 10% phosphoric acid and the aqueous layer was made alkaline with saturated sodium bicarbonate solution (pH=8-9). The product was extracted with ether (2×25 mL), dried over anhydrous potassium carbonate, and concentrated under reduced pressure to give 4.36 g (80%) of the amine (3B) as a light yellow liquid. The NMR spectrum exhibited a structure that was consistent with the proposed structure. ¹H NMR (CDCl₃): δ 1.04 (t, 3H), 1.26 (d, 3H), 2.11 (s, 3H), 2.25-2.48 (m, 2H), 3.50 (q, 1H), 4.45-4.55 (m, 4H), 4.5 (s, 5H)

### Example 11

### Synthesis of [1-(Isopropylmethylamino)Ethyl]Ruthenocene

The synthesis was conducted as described in Example 10 except that the amine used was isopropylmethylamine. The NMR spectrum was consistent with the proposed structure. ¹H NMR (CDCl₃): δ 0.97 (t, 6H), 1.26 (d, 3H), 2.11 (s, 3H), 2.86 (m, 1H), 3.65 (q, 1H), 4.43-4.58 (m, 4H), 4.49 (s, 5H).

### Example 12

### Synthesis of [1-(Methylpropylamino)Ethyl]Ruthenocene

The synthesis was conducted as described in Example 10 except the amine used was methylpropylamine. The NMR spectrum was consistent with the proposed structure. ¹H NMR (CDCl₃): δ0.87 (t, 3H), 1.24 (d, 3H), 1.43 (m, 2H), 2.11 (s, 3H), 2.22 (m, 2H), 3.47 (q, 1H), 4.46-4.56 (m, 4H), 4.49 (s, 5H)

### Example 13

### Synthesis of [1-(Ethylisopropylamino)Ethyl]Ruthenocene

The synthesis was conducted as described in Example 10 except the amine used was ethylisopropylamine. The NMR spectrum was consistent with the proposed structure. ¹H NMR (CDCl₃): δ 0.91 (d, 3H), 1.01 (t, 6H), 2.53 (q, 2H), 3.09 (m, 1H), 3.7 (q, 1H) 4.46-4.66 (m, 4H), 4.56 (s, 5H)

### Example 14

### Synthesis of [1-(^{N}Butylpropylamino)Ethyl]Ruthenocene

The synthesis was conducted as described in Example 10 except the amine used was n-butyl-n-propylamine. The NMR spectrum was consistent with the proposed structure. ¹H NMR (CDCl₃): δ 0.87 (t, 3H), 0.91 (t, 3H), 1.21 (d, 3H), 1.27-1.45 (m, 6H), 2.19-2.41 (m, 4H), 3.59 (q, 1H), 4.45-4.61 (m, 4H), 4.52 (s, 5H).

### Example 15

### Synthesis of [1-(Methylbutylamino)Ethyl]Ruthenocene (3C)

The synthesis was conducted as described in Example 10 except the amine used was methyl-n-butylamine. The NMR spectrum was consistent with the proposed structure. ¹H NMR (CDCl₃): δ 0.89 (t, 3H), 1.24 (d, 3H), 1.27-1.45 (m, 4H), 2.1 (s, 3H), 2.17-2.39 (m, 2H), 3.45, (q, 1H), 4.45-4.58 (m, 4H), 4.49 (s, 5H)

### Example 16

### Synthesis of [1-(Di^{N}Propylamino)Ethyl]Ruthenocene

The synthesis was conducted as described in Example 10 except the amine used was di-n-propylamine. The NMR spectrum was consistent with the proposed structure. ¹H NMR (CDCl₃): δ 0.84 (t, 6H), 1.19 (d, 3H), 1.33-1.45 (m, 4H), 2.17-2.35 (m, 4H), 3.36 (q, 1H), 4.45-4.56 (m, 4H), 4.49 (s, 5H)

### Example 17

### Synthesis of [1-(Diisopropylamino)Ethyl]Ruthenocene

The synthesis was conducted as described in Example 10 except the amine used was di-isopropylamine. The NMR spectrum was consistent with the proposed structure. ¹H NMR (CDCl₃): δ 0.93 (d, 6H), 1.01 (d, 6H), 1.19 (d, 3H), 3.18 (m, 2H), 3.76 (q, 1H), 4.42-4.66 (m, 4H), 4.49 (s, 5H)

### Example 18

### Synthesis of [1-(Diethylamino)Ethyl]Ruthenocene (3D)

The synthesis was conducted as described in Example 10 except the amine used was diethylamine. The NMR spectrum was consistent with the proposed structure. ¹H NNMR (CDCl₃): δ 1.01 (t, 6H), 1.23 (d, 3H), 2.27-2.34 (m, 2H), 2.44-2.55 (m, 2H), 3.60 (q, 1H), 4.44-4.56 (m, 4H), 4.49 (s, 5H)

### Example 19

### Synthesis of [1-(Dimethylamino)Ethyl]Ruthenocene (3A)

The synthesis was conducted as described in Example 10 except that the amine used was dimethylamine. The NMR spectrum was consistent with the proposed structure. ¹H NMR (CDCl₃): δ 1.27 (d, 3H), 2.16 (s, 3H), 3.31 (q, 1H), 4.44-4.48 (m, 4H), 4.51 (s, 5H). Elemental analysis: calculated for C₁₄H₁₉NRu: C, 55.61%; H, 6.33%; N, 4.63%; Ru, 33.43%. found: C, 55.59%; H, 6.25%; N, 4.58%, and Ru, 33.5%.

### Example 20

### Synthesis of [1-(Cyclohexylmethylamino)Ethyl]Ruthenocene

The synthesis was conducted as described in Example 10 except the amine used was changed to methylcyclohexylamine. The NMR spectrum was consistent with the proposed structure. ¹H NMR (CDCl₃): δ 1.05-1.21 (m, 4H), 1.25 (d, 3H), 1.56-1.73 (m, 6H), 2.15 (s, 3h), 3.63 (q, 1H), 4.43-4.59 (m, 4H), 4.49 (s, 5H)

### Example 21

### Synthesis of [(Dimethylamino)Methyl]Ruthenocene

Reaction of bis(cyclopentadienyl)ruthenium with bis(dimethylamino)methane in acetic acid in presence of phosphoric acid catalyst gave [(dimethylamino)methyl]ruthenocene as a yellow solid with a melting point of 39-41° C. in 80% yield. NMR spectrum was consistent with the proposed structure.

### Example 22

### Thermal ALD of Ruthenium Using 1 Hydroxyethylruthenocene (2A) and Air at 275-400° C.

In this example, 1-hydroxyethylruthenocene (2A) was used as a ruthenium containing organometallic precursor for ALD ruthenium film synthesis in a flow type F-120 ALD reactor manufactured by ASM Microchemistry. Air was used as a co-reactant and N₂ was used as a purge gas. The evaporation temperature of 1-hydroxyethylruthenocene used during the growth experiments was 110-114° C. The structure and growth for the films grown were examined in the substrate temperature range of 275-350° C. Air flow rate was kept at 20 sccm. The ruthenium precursor pulse, purge, air pulse and the second purge times were shown in Table 1. ruthenium films were all grown on an Al₂O₃ seed layer that was grown at the same temperature right before ruthenium from Al(CH₃)₃ and H₂O on SiO₂/Si and soda lime glass substrates, using 200 cycles with time parameters 0.2-0.5-0.5-0.5 s [Al(CH₃)₃ pulse time-N₂ purge time-H₂O pulse time and N₂ purge time]. (Table 1)

TABLE 1

| | | | | growth | Sheet | |
|---|---|---|---|---|---|---|
| | | | Thickness | rate | resistance, | resistivity |
| Run | Growth temp. | Cycles | (nm) | nm/cycle | R_{□}, Ω | μΩ · cm |
| 1 | 275° C. | 1000 × 2-1- | no film | — | — | — |
| | | 1-1 s | | | | |
| 2 | 290° C. | 500 × 4-1-2- | no film | — | — | — |
| | | 1 s | | | | |
| 3 | 300° C. | 1000 × 2-1- | 18 | 0.018 | 7.1-11.7 | 15.0 |
| | | 1-1 s | | | | |
| 4 | 300° C. | 400 × 4-1-2- | 5 | 0.013 | 250-1990 | 560 |
| | | 1 s | | | | |
| 5* | 325° C. | 1000 × 1- | 24 | 0.024 | 5.3-35.3 | 48.7 |
| | | 0.5-1-0.5 s | | | | |
| 6 | 325° C. | 1000 × 1-1- | 18 | 0.018 | 4.5-34.7 | 20.0 |
| | | 1-1 s | | | | |
| 7 | 325° C. | 1000 × 2-1- | 32 | 0.032 | 3.8-6.2 | 16.2 |
| | | 1-1 s | | | | |
| 8 | 325° C. | 1000 × 3-1- | 24 | 0.024 | 3.7-8.4 | 17.9 |
| | | 1-1 s | | | | |
| 9 | 325° C. | 1000 × 3-1- | 35 | 0.035 | 3.1-5.7 | 15.4 |
| | | 1-1 s | | | | |
| 10 | 325° C. | 1000 × 4.5- | 39 | 0.039 | 2.8-3.1 | 11.5 |
| | | 1-1-1 s | | | | |
| 11 | 325° C. | 1000 × 6-1- | 34 | 0.034 | 3.0-3.9 | 13.6 |
| | | 1-1 s | | | | |
| 12 | 325° C. | 700 × 2-1-1- | 17 | 0.024 | 6.5-12.7 | 13.6 |
| | | 1 s | | | | |
| 13 | 325° C. | 400 × 2-1-1- | 7 | 0.018 | 27.4-376.6 | 57.5 |
| | | 1 s | | | | |
| 14 | 325° C. | 325 × 2-1-1- | ca. 2 | 0.006 | unmeasurable | — |
| | | 1 s | | | | |
| 15 | 325° C. | 250 × 2-1-1- | <1 | ca. 0.002 | unmeasurable | — |
| | | 1 s | | | | |
| 16 | 350° C. | 325 × 2-1-1- | 10 | 0.031 | 15.1-140.0 | 77.5 |
| | | 1 s | | | | |
| 17 | 400° C. | 325 × 2-1-1- | 16 | 0.049 | 8.5-10.7 | 15.5 |
| | | 1 s | | | | |

For run # 5, the evaporation temperature is 105° C.
In the “Cycles column”, the sequence is number of cycles, ruthenium precursor pulse, N₂ purge time, air pulse time and N₂ purge time.

The thicknesses of the films were calculated from the energy-dispersive X-ray analysis data, as shown in Table 1, and were measured in the middle of the substrate, at about 25 mm distance from the leading edge of the substrate along the gas flow direction.

Noticeable film growth was not achieved below 300° C. The average growth rate above 300° C. tended to saturate with the 1-hydroxyethylruthenocene pulse length. The incubation (seed) time before the start of the growth process is long, the efficient growth requires at least 300-400 preparatory cycles at about 300-325° C. Long incubation time has been reported for the RuCp₂-O₂ process, and its length was found to have strong temperature dependence.

The growth rate increased from 0.018 to 0.049 nm/cycle with the substrate temperature increasing from 300 to 400° C., similarly to the RuCp₂-O₂ process. In addition, the seed was faster at the beginning of the growth at higher temperatures, decided on bases of the runs with 325 deposition cycles carried out at 325, 350 and 400° C., respectively.

### Example 23

### Thermal ALD of Ruthenium Using [1-(Dimethylamino)Ethyl]Ruthenocene(3A) and Air at 325-500° C.

In another example of the embodiment, [1-(dimethylamino)ethyl]ruthenocene (3A) was used for thermal ALD ruthenium film synthesis similar to 1-hydroxyethylruthenocene. The [1-(dimethylamino)ethyl]ruthenocene evaporation temperature tested during the growth experiments was 75-105° C. The growth was examined in the substrate temperature range of 325-500° C. The other reactant was air with a flow rate of 25 sccm. The precursor pulse length was varied between 1 and 10 sec, while the first purge, air pulse and the second purge times were kept constant at 1 sec (Table 2). Ruthenium films were grown on an Al₂O₃ seed layer that was grown at the same temperature right before ruthenium from Al(CH₃)₃ and H₂O on SiO₂/Si and soda lime glass substrates, with cycle times 0.2-0.5-0.5-0.5 s [Al(CH₃)₃ pulse time-N₂ purge time-H₂O pulse time and N₂ purge time]. 200 cycles of Al₂O₃ growth were always applied.

TABLE 2

| | | | | | growth | Sheet | |
|---|---|---|---|---|---|---|---|
| | Evap. | Growth | | | rate | resistance, | resistivity |
| Run | temp. | temp. | Cycles | Thickness (nm) | nm/cycle | R_{□}, Ω | μΩ · cm |
| 1 | 105° C. | 325° C. | 1000 × | grown only on | — | — | — |
| | | | 2-1-1-1 s | the leading | | | |
| | | | | edge | | | |
| 2 | 75° C. | 325° C. | 1000 × | profiled, | 0.020 | 5.1-25.5 | 30 |
| | | | 2-1-1-1 s | 20 nm @ middle | | | |
| 3 | 85° C. | 350° C. | 1000 × | 23 nm | 0.023 | 4.5-9.8 | 16.4 |
| | | | 2-1-1-1 s | | | | |
| 4 | 75° C. | 350° C. | 500 × | strongly profiled | 0.024 | 9.6-34.3 | 26.3 |
| | | | 2-1-1-1 s | 12 nm @ middle | | | |
| 5 | 75° C. | 350° C. | 500 × | grown only on | | | |
| | | | 5-1-1-1 s | the leading | | | |
| | | | | edge | | | |
| 6 | 75° C. | 350° C. | 500 × | grown only on | | | |
| | | | 6-1-1-1 s | the leading | | | |
| | | | | edge | | | |
| 7 | 95° C. | 375° C. | 1000 × | 37 nm | 0.037 | 3.8-4.5 | 16.4 |
| | | | 2-1-1-1 s | | | | |
| 8 | 75° C. | 400° C. | 1000 × | 52 nm | 0.052 | 3.2-5.4 | 22.3 |
| | | | 2-1-1-1 s | | | | |
| 9 | 75° C. | 400° C. | 500 × | 23 nm | 0.046 | 5.5-6.9 | 14.2 |
| | | | 5-1-1-1 s | | | | |
| 10 | 75° C. | 400° C. | 500 × | 23 nm | 0.046 | 5.5-7.3 | 14.7 |
| | | | 2-1-1-1 s | | | | |
| 11 | 75° C. | 400° C. | 500 × | 23 nm | 0.046 | 5.9-7.0 | 14.8 |
| | | | 1-1-1-1 s | | | | |
| 12 | 75° C. | 400° C. | 150 × | 4 nm | 0.027 | 42.3-203.8 | 49 |
| | | | 2-1-1-1 s | | | | |
| 13 | 75° C. | 450° C. | 200 × | 8.9 nm* | 0.045 | 17.3-18.7 | 16.0 |
| | | | 10-1-1-1 s | | | | |
| 14 | 75° C. | 450° C. | 200 × | 10.1 nm* | 0.051 | 13.1-14.0 | 13.5 |
| | | | 6-1-1-1 s | | | | |
| 15 | 75° C. | 450° C. | 200 × | 9.9 nm* | 0.050 | 13.1-15.4 | 14.1 |
| | | | 2-1-1-1 s | | | | |
| 16 | 75° C. | 450° C. | 100 × | 5.8 nm* | 0.058 | 163-543 | 204.7 |
| | | | 2-1-1-1 s | | | | |
| 17 | 75° C. | 500° C. | 200 × | 14.0 nm* | 0.07 | 8.6-12.6 | 14.8 |
| | | | 6-1-1-1 s | | | | |
| 18 | 75° C. | 500° C. | 200 × | 16.0 nm* | 0.08 | 12.6-25.6 | 30.6 |
| | | | 2-1-1-1 s | | | | |
| 19 | 75° C. | 500° C. | 100 × | 5.0 nm* | 0.050 | Not | — |
| | | | 2-1-1-1 s | | | measurable | |

These thicknesses are measured by X-ray reflectance (XRR), others by EDX.
In the “Cycles column”, the sequence is number of cycles, ruthenium precursor pulse, N₂ purge time, air pulse time and N₂ purge time

At 400° C. the film growth rate was independent of the [1-(dimethylamino)ethyl]ruthenocene precursor pulse length in the range of 1-5 s, being indicative of the self-limiting growth characteristic to ALD. At this high temperature this result may be considered remarkable, and even more remarkable is that the growth rate did not increase with the [1-(dimethylamino)ethyl]ruthenocene pulse length even at 450 and 500° C., referring to the exceptional thermal stability of the precursor.

Table 2 also shows that increasing the [1-(dimethylamino)ethyl]ruthenocene pulse length in the temperature range of 400-500° C. did not cause increase in the growth rate per cycle, being indicative of self-limiting ALD growth behaviour up to this temperature.

One run was made at 450° C. with [1-(dimethylamino)ethyl]ruthenocene pulse length as long as 10 seconds, in order to check that the growth is self-limiting at this surprisingly high temperature. As the growth rate per cycle remains essentially unchanged, this self-limiting growth is confirmed.

### Example 24

### Thermal ALD of Ruthenium Using [1-(Dimethylamino)Ethyl]Ruthenocene (3A) and Oxygen at 300-350° C.

In another example of the embodiment, [1-(dimethylamino)ethyl]ruthenocene (3A) was used as ruthenium containing organometallic precursor for ALD Ru film synthesis in a flow type F-120 SAT ALD reactor manufactured by ASM Microchemistry at deposition temperature in the range of 300-350° C. Pure oxygen was used as a co-reactant and N₂ was used as purge gas. The [1-(dimethylamino)ethyl]ruthenocene evaporation temperature used during the growth experiments was 85° C. The oxygen flow rate was between 100-150 sccm. The [1-(dimethylamino)ethyl]ruthenocene pulse, purge, air pulse and the second purge times were all 2 seconds. Ruthenium films were all grown on an Al₂O₃ seed layer that was grown at the same temperature right before ruthenium from Al(CH₃)₃ and H₂O on native SiO₂/Si using 250 cycles with time parameters 0.5-2-1-2 s [Al(CH₃)₃ pulse time-N₂ purge time-H₂O pulse time and N₂ purge time)

After 600 cycles of deposition, shiny metallic ruthenium films were formed on the substrate surface for all the deposition temperatures. The film has a deposition rate of 0.026 nm/cycle and resistivity of 24 μΩ·cm for 350° C. deposition temperature and 130 sccm oxygen flow rate. The film sheet resistance is 57-76 Ω/square for 300° C. deposition temperature with oxygen flow rate at 150 sccm and 12-16 Ω/square for 325° C. with oxygen flow rate at 150 sccm.

### Example 25

### Thermal ALD of Ruthenium Using [1-(Ethylmethylamino)ethyl]ruthenocene(3B) and air & oxygen at 325-425° C.

In another example of the embodiment, a liquid ruthenium metalorganic precursor [1-(ethylmethylamino)ethyl]ruthenocene (3B) was used as a ruthenium containing organometallic precursor for ALD ruthenium film synthesis in a flow type F-120 SAT ALD reactor. Both pure oxygen and air were used as co-reactants and N₂ was used as purge gas. The [1-(ethylmethylamino)ethyl]ruthenocene (3B) evaporation temperature used during the growth experiments was 85° C. The [1-(ethylmethylamino)ethyl]ruthenocene pulse, purge, air pulse and the second purge times were all 2 seconds. Ruthenium films were all grown on an Al₂O₃ seed layer that was grown at the same temperature right before ruthenium from Al(CH₃)₃ and H₂O on native SiO₂/Si using 250 cycles with time parameters 0.5-2-1-2 s [Al(CH₃)₃ pulse time-N₂ purge time-H₂O pulse time and N₂ purge time].

After 600 cycles of deposition, metallic films were formed on the substrate surface. When the air flow rate was 100 sccm and the deposition temperature was 350° C., the resulting film sheet resistance is 9 Ω/square; when the air flow rate is 20 sccm for 425° C. deposition temperature, the film sheet resistance is 5.7 Ω/square When the oxygen flow rate was between 110 sccm for 325° C. deposition temperature, the film sheet resistance is 11-13 Ω/square. When the oxygen flow rate was 15 sccm for 375° C. deposition temperature, the film has a deposition rate of 0.035 nm/cycle and resistivity of 25 μΩ·cm.

### Example 26

### Thermal ALD of Ruthenium Using [1-(^{N}Butylmethylamino)Ethyl]Ruthenocene (3C) and Oxygen at 325-350° C.

In another example of the embodiment, yet another liquid ruthenium metalorganic precursor [1-(ⁿbutylmethylamino)ethyl]ruthenocene (3C) was used as a ruthenium containing organometallic precursor for ALD ruthenium film synthesis in a flow type F-120 SAT ALD reactor. Pure oxygen was used as a co-reactant and N₂ was used as purge gas. The [1-(ⁿbutylmethylamino)ethyl]ruthenocene (3C) evaporation temperature used during the growth experiments was 95° C. The [1-(ⁿbutylmethylamino)ethyl]ruthenocene pulse, purge, air pulse and the second purge times were all 2 seconds. Ruthenium films were all grown on an Al₂O₃ seed layer that was grown at the same temperature right before ruthenium from Al(CH₃)₃ and H₂O on native SiO₂/Si using 250 cycles with time parameters 0.5-2-1-2 s [Al(CH₃)₃ pulse time-N₂ purge time-H₂O pulse time and N₂ purge time]. After 600 cycles of deposition, metallic films were formed on the substrate surface. When the oxygen flow rate is 35 sccm for substrate temperature of 350° C., the film sheet resistance is 14.1 Ω/square in average. When the oxygen flow rate is 110 sccm for substrate temperature of 325° C., the film sheet resistance is 19 Ω/square in average.

### Example 27

### Thermal ALD of Thin Ruthenium Films Using [1-(Diethylamino)Ethyl]Ruthenocene (3D) and Oxygen at 350° C.

In another example, yet another liquid Ru metalorganic precursor [1-(diethylamino)ethyl]ruthenocene was used as a metal containing organometallic precursor for ALD ruthenium film synthesis in a flow type F-120 SAT ALD reactor. Pure oxygen was used as a co-reactant and N₂ was used as purge gas. The [1-(diethylamino)ethyl]ruthenocene evaporation temperature used during the growth experiments was 85° C. The [1-(diethylamino)ethyl]ruthenocene pulse, purge, air pulse and the second purge times were all 2 seconds. Ruthenium films were all grown on an Al₂O₃ seed layer that was grown at the same temperature right before ruthenium from Al(CH₃)₃ and H₂O on native SiO₂/Si using 250 cycles with time parameters 0.5-2-1-2 s [Al(CH₃)₃ pulse time-N₂ purge time-H₂O pulse time and N₂ purge time]. After 600 cycles of deposition, shiny metallic films were formed on the substrate surface. When the oxygen flow rate is 65 sccm and the deposition temperature is 350° C., the resulting film sheet resistance is 14.6 Ω/square in average.

### Example 28

### Thermal ALD of Ruthenium Using [(Dimethylamino)Methyl]Ruthenocene and Oxygen at 350° C.

In another example of the embodiment, a solid ruthenium metalorganic precursor [(dimethylamino)methyl]ruthenocene was used as a ruthenium containing organometallic precursor for ALD ruthenium film synthesis in a flow type F-120 SAT ALD reactor. Oxygen was used as co-reactants.

The [1-(dimethylamino)methyl]ruthenocene evaporation temperature used during the growth experiments was 85° C. The [1-(dimethylamino)methyl]ruthenocene pulse, purge, air pulse and the second purge times were all 2 seconds. Ruthenium films were all grown on an Al₂O₃ seed layer that was grown at the same temperature right before ruthenium from Al(CH₃)₃ and H₂O on native SiO₂/Si using 250 cycles with time parameters 0.5-2-1-2 s (Al(CH₃)₃ pulse time-N₂ purge time-H₂O pulse time and N₂ purge time). After 600 cycles of deposition, metallic films were formed on the substrate surface. When the oxygen flow rate is 35 sccm for substrate temperature of 350° C., the ruthenium film sheet resistance is 13.5 Ω/square in average.

### Example 29

### PEALD of Ruthenium Films Using 1-Hydroxyethylruthenocene (2A)

Ru films were deposited by PEALD on three types of substrates: thermal 1 um SiO₂, 18 nm HfO₂, ALD TaN. The PEALD tool was modified from 200 mm wafer MOCVD equipment. NH₃ and N₂ plasma were used to enhance the reduction of the Ru precursor, 1-hydroxyethylruthenocene. Table 3 illustrates the deposition conditions. The precursor 2A was loaded into a precursor container and heated to 125-145° C. A typical deposition cycle consists of four consecutive pulses: 1-hydroxyethylruthenocene pulse, argon purge pulse, NH₃ or N₂ plasma pulse and argon purge pulse. Film thickness was analyzed using cross sectional field emission scanning electron microscopy (FE-SEM). The film composition was analyzed using X-ray photoelectron spectroscopy (XPS), Rutherford backscattering spectroscopy (RBS) and secondary ion mass spectroscopy (SIMS). AFM and FE-SEM were used to evaluate the film surface smoothness. FE-SEM was also used to evaluate the conformity of Ru films deposited on patterned PVD TaN/SiO₂/Si. Scotch tape peel-off test was used to evaluate the adhesion of ruthenium film to underlayers.

TABLE 3

| Chamber pressure | 1 Torr |
|---|---|
| Plasma power | 25-150 W, 90 KHz |
| Plasma frequency | 90 kHz |
| Ruthenium precursor (2A) pulse length | 3-16 seconds |
| Ar/NH₃/Ar pulse length | 15 sec/variable/15 sec |
| Ruthenium precursor (2A) flow rate | 0.5 sccm |
| Ar flow rate | 50 sccm |
| NH₃ or N₂ flow rate | 50 sccm |
| Substrate temperature | 300° C. |
| Number of deposition cycles | 25-600 |

TABLE 4

| | | | | Ru | NH₃ | Film thickness | | | Deposition rate | | | Resistivity | |
|---|---|---|---|---|---|---|---|---|---|---|---|---|---|
| | | | Plasma | precursor | pulse | (nm) | | | (nm/cycle) | | | (μΩ-cm) | |
| | T | | power | (2A) pulse | time | On | On | On | On | On | On | On | On |
| Run | (° C.) | Cycles | (W) | time | (s) | SiO₂ | HfO₂ | TaN | SiO₂ | HfO₂ | TaN | SiO₂ | HfO₂ |
| 1 | 300 | 600 | 150 | 3 | 15 | 10.1 | 10.1 | 12.3 | 0.017 | 0.017 | 0.021 | 34 | 26 |
| | | | | | (N₂) | | | | | | | | |
| 2 | 300 | 600 | 150 | 3 | 15 | 22.9 | 15.9 | 16.2 | 0.038 | 0.027 | 0.027 | 59 | 57 |
| 3 | 300 | 600 | 150 | 8 | 15 | 35.7 | 34.2 | 20.7 | 0.06 | 0.057 | 0.035 | 35 | 32 |
| 4 | 300 | 600 | 150 | 8 | 25 | 46.7 | 50, | 47 | 0.078 | 0.083, | 0.078 | 12 | 12, |
| | | | | | | | 87.5 | | | 0.146 | | | 14 |
| 5 | 300 | 200 | 150 | 8 | 25 | 12.3 | 16.9 | 12.3 | 0.062 | 0.085 | 0.062 | 24 | 23 |
| 6 | 300 | 400 | 150 | 8 | 25 | 33.3 | 50.9 | 29.0 | 0.083 | 0.127 | 0.073 | 19 | 13 |
| 7 | 300 | 200 | 150 | 12 | 25 | 16.0 | 29.2 | 17.4 | 0.08 | 0.146 | 0.087 | 23 | 20 |
| 8 | 300 | 200 | 150 | 16 | 25 | 16.7 | 27.2 | 18 | 0.084 | 0.136 | 0.09 | 26 | 13 |
| 9 | 300 | 50 | 150 | 8 | 25 | 2.5 | 4 | 2.5 | 0.05 | 0.08 | 0.05 | 86 | 84 |
| 10 | 300 | 25 | 150 | 8 | 25 | 1.7 | 2.4 | 1.4 | 0.068 | 0.096 | 0.056 | 317 | 179 |
| 11 | 300 | 100 | 150 | 8 | 25 | 6.5 | 11.2 | 7 | 0.065 | 0.112 | 0.07 | 30 | 21 |
| 12 | 300 | 600 | 50 | 1 | 15 | 16.5 | | 17.5 | 0.028 | — | 0.029 | 19 | — |
| 13 | 300 | 600 | 25 | 3 | 15 | 4.1 | | 6.1 | 0.007 | — | 0.01 | 107 | — |

Nitrogen or NH₃ plasmas were used as a co-reactant to carry out the deposition of ruthenium thin films. Film deposition rate and resistivity are strongly affected by plasma power, ruthenium precursor (2A) and NH₃ pulse times (Table 4). To achieve a deposition rate of 0.08 nm/cycle or higher, a plasma power of 150 W, NH₃ pulse time of 25 seconds and ruthenium precursor (2A) pulse time of 8 seconds are needed. This growth rate is significantly higher than the rates reported in the literature for PEALD of ruthenium films with industry bench marks such as bis(cyclopentadienyl)ruthenium and bis(ethylcyclopentadienyl)ruthenium. At 300° C. and 150 W plasma power the film growth rate is independent of the ruthenium precursor pulse length in the range of 8-16 s, being indicative of the self-limiting growth characteristic to ALD.

The films also have low resistivity at these optimized deposition conditions. At film thickness of less than 2 nm for only 25 cycles of deposition, the film resistivity is several hundred μΩ-cm demonstrating the excellent seed of the film with 1-hydroxyethylruthenocene (2A). Top SEM and cross section TEM views show that the films are continuous at >=25 deposition cycles. The continuity and low resistivity of films obtained by this method have potential for interconnect diffusion barrier/adhesion layer/seed layer applications and DRAM capacitor bottom electrode applications. The ruthenium films deposited have very low impurity levels and SIMS compositional analysis of run 4 and run 6 Ru/SiO₂ samples shows C, N, and O impurity level below 0.15 at. %. Run #1 show that N₂ plasma can also be used to deposit Ru films. However, the deposition rate is less than NH₃ plasma at comparable conditions.

### Example 30

### PEALD of Ruthenium Films with N₂ Plasma Using [1-(Dimethylamino)Ethyl]Ruthenocene, C₅H₅—Ru—O₅H₄—CH(CH₃)N(CH₃)₂ (3A)

Ruthenium films were deposited by PEALD using N₂ plasma and [1-(dimethylamino)ethyl]ruthenocene (3A) as ruthenium containing precursor. Three different types of substrates, such as 1 μm SiO₂, 18 nm HfO₂, and ALD TaN were used to deposit the ruthenium films and deposition conditions are described in Table 5. The film composition was analyzed using XPS and SIMS. The film thickness, deposition rate and resistivity are reported in Table 6 (runs 20-22).

Surprisingly, the ruthenium films grew utilizing N₂ plasma and the ruthenium precursor 3A under the growth conditions described herein (Table 5) possess low resistivity, high film smoothness, and good growth rate. These films also adhere well to the substrates without de-bonding. These attributes are critical to the application of ruthenium films in semiconductor chips manufacturing. Furthermore, use of nitrogen plasma to deposit ruthenium thin films results in lower costs of operation and less damage to the substrate materials.

TABLE 5
PEALD processing conditions

| Chamber pressure | 0.7 Torr |
|---|---|
| Plasma power | 50-150 W |
| Plasma frequency | 90 kHz |
| Ruthenium precursor 3A pulse length | 1 second |
| Ar/N₂/Ar pulse length | 10 sec/15 sec/10 sec |
| Ruthenium precursor 3A flow rate | 0.5 sccm |
| Ar flow rate | 50 sccm |
| N₂ flow rate | 50 sccm |
| Substrate temperature | 350° C. |
| Number of deposition cycles | 450 |

TABLE 6

| | | | | | | | | | | | | | | | Surf. |
|---|---|---|---|---|---|---|---|---|---|---|---|---|---|---|---|
| | | | | Ru | | | | | | | | | | | Rough. |
| | | | | precursor | | | Film thickness | | | Deposition rate | | | Resistivity | | (RMS) |
| | | | Plasma | (3A) | Ar | NH₃ | (nm) | | | (nm/cycle) | | | (μΩ-cm) | | (nm) |
| | T | | power | pulse | purge | pulse | On | On | On | On | On | On | On | On | On |
| Run | (C.) | Cyc. | (W) | time (s) | time (s) | time (s) | SiO₂ | HfO₂ | TaN | SiO₂ | HfO₂ | TaN | SiO₂ | HfO₂ | SiO₂ |
| 1 | 275 | 250 | 300 | 16 | 25 | 25 | 24.1 | 25.8 | 24.6 | 0.096 | 0.103 | 0.098 | 17 | 11 | 0.6 |
| 2 | 375 | 150 | 300 | 16 | 25 | 50 | 27.9 | 31.7 | 39 | 0.186 | 0.211 | 0.26 | 12 | 13 | 0.66 |
| 3 | 275 | 150 | 300 | 8 | 25 | 50 | 26.3 | 20.1 | 22.3 | 0.175 | 0.134 | 0.149 | 18 | 13 | 0.56 |
| 4 | 275 | 225 | 150 | 16 | 25 | 50 | 31.7 | 47.4 | 31.7 | 0.141 | 0.211 | 0.141 | 16 | 13 | 0.56 |
| 5 | 375 | 175 | 150 | 16 | 25 | 25 | 19.5 | 21 | 19.9 | 0.111 | 0.12 | 0.114 | 27 | 20 | 0.3 |
| 6 | 325 | 200 | 225 | 12 | 25 | 38 | 23.5 | 23.5 | 26.9 | 0.118 | 0.118 | 0.135 | 21 | 18 | 0.35 |
| 7 | 325 | 200 | 225 | 12 | 25 | 38 | 23.3 | 22.9 | 30.3 | 0.117 | 0.115 | 0.152 | 20 | 16 | 0.39 |
| 8 | 375 | 175 | 150 | 8 | 25 | 50 | 20.1 | 21.2 | 20 | 0.115 | 0.121 | 0.114 | 27 | 20 | 0.5 |
| 9 | 275 | 325 | 150 | 8 | 25 | 25 | 22.9 | 17.2 | 23.5 | 0.07 | 0.053 | 0.072 | 22 | 27 | 0.51 |
| 10 | 375 | 250 | 300 | 8 | 25 | 25 | 32.7 | 30.9 | 34.9 | 0.131 | 0.124 | 0.14 | 16 | 18 | 0.75 |
| 11 | 325 | 200 | 225 | 12 | 25 | 38 | 24 | 25.2 | 25.8 | 0.12 | 0.126 | 0.129 | 17 | 14 | 0.5 |
| 12 | 275 | 125 | 300 | 16 | 25 | 50 | 23.5 | 18.9 | 30.7 | 0.188 | 0.151 | 0.246 | 23 | 17 | 0.62 |
| 13 | 275 | 7 | 300 | 16 | 25 | 50 | 1.8 | 1.24 | 1.4 | 0.257 | 0.177 | 0.2 | 235 | 87 | 0.30 |
| 14 | 275 | 13 | 300 | 16 | 25 | 50 | 2.15 | 1.3 | 3.1 | 0.165 | 0.1 | 0.238 | 61 | 65 | 0.21 |
| 15 | 275 | 30 | 300 | 16 | 25 | 50 | 4.65 | 4.6 | 3.9 | 0.155 | 0.153 | 0.13 | 46 | 37 | 0.28 |
| 16 | 275 | 50 | 300 | 16 | 25 | 50 | 12.4 | 12 | 9 | 0.248 | 0.24 | 0.18 | 28 | 34 | 0.29 |
| 17 | 350 | 600 | 50 | 1 | 15 | 25 | 18.3 | 16.1 | 19.9 | 0.031 | 0.027 | 0.033 | 35 | 24 | — |
| 18 | 350 | 600 | 100 | 3 | 15 | 25 | 30.2 | 31 | 30.1 | 0.05 | 0.052 | 0.05 | 18 | 16 | 0.58 |
| 19 | 350 | 600 | 150 | 3 | 15 | 25 | 23.7 | 22 | 21.8 | 0.04 | 0.037 | 0.036 | 19 | 16 | — |
| 20 | 350 | 450 | 50 | 1 | 10 | 15 (N2) | 16 | 15.8 | 15 | 0.036 | 0.035 | 0.033 | 33 | 31 | — |
| 21 | 350 | 450 | 100 | 1 | 10 | 15 (N2) | 16.7 | 14 | 17.1 | 0.037 | 0.031 | 0.038 | 26 | 22 | 0.37 |
| 22 | 350 | 450 | 150 | 1 | 10 | 15 (N2) | 17.3 | 16.9 | 16.3 | 0.038 | 0.038 | 0.036 | 28 | 27 | — |

Note:
Run 1-16, PVD TaN substrate and Run 17-22 ALD TaN substrate

### Example 31

### PEALD of Ruthenium Films with NH₃ Plasma Using [1-(Dimethylamino)Ethyl]Ruthenocene, C₅H₅—Ru—O₅H₄—CH(CH₃)N(CH₃)₂ (3A)

Ruthenium films were deposited by PEALD using NH₃ plasma and [1-(dimethylamino)ethyl]ruthenocene (3A) as ruthenium containing precursor. Three different types of substrates, such as 1 μm SiO₂, 18 nm HfO₂, patterned PVD and ALD TaN were used to deposit the ruthenium films and deposition conditions are described in Table 7. Film thickness was analyzed using cross sectional FE-SEM and RBS. FE-SEM was also used to evaluate the conformity of ruthenium films deposited on patterned PVD TaN.

TABLE 7
PEALD processing conditions

| Chamber pressure | 0.7 Torr |
|---|---|
| Plasma power | 50-300 W |
| Plasma frequency | 90 kHz |
| Ruthenium precursor 3A pulse length | 1-16 seconds |
| Ar/NH₃/Ar pulse length | variable/variable/ |
| | variable |
| Ruthenium precursor 3A flow rate | 0.5 sccm |
| Ar flow rate | 50 sccm |
| N₂ flow rate | 50 sccm |
| Substrate temperature | 275-375° C. |
| Number of deposition cycles | 7-600 |

With 50-150 W plasma power and a ruthenium precursor (3A) pulse time of 1-3 seconds and NH₃ pulse time of 25 seconds, the ruthenium film growth rate was in the range of 0.027-0.052 nm/cycle.

In order to find out the optimal deposition conditions, a “Design of Experimental” (DOE) study composed of 11 runs with a mid point was initiated. In this design, substrate temperature, plasma power and ammonia pulse time were selected as the three variables with growth rate, resistivity and surface roughness were the three measurable outputs. The substrate temperature, plasma power and NH₃ pulse times were kept in the range of 275-375° C.; 150-300 W and 25-50 seconds, respectively. Number of deposition cycles was varied for every run to maintain the film thickness close to 20-30 nm. The film thickness, deposition rate, resistivity and surface roughness results are reported in Table 6 (Runs 1-11).

It was observed that in general the film deposition rate increases with increasing plasma power, ammonia pulse and ruthenium precursor (3A) pulse times. The film resistivity decreases with increasing plasma power. The ruthenium films obtained in this study using [1-(dimethylamino)ethyl]ruthenocene (3A) as the ruthenium precursor were very smooth and the surface roughness as studied by AFM was much lower than that obtained by thermal ALD process. SIMS study of the ruthenium film deposited on SiO₂ substrate for runs 14 to 16 showed carbon, nitrogen and oxygen impurity levels below 0.25%. The ruthenium film deposited on a patterned PVD TaN substrate (run 7) showed bottom step coverage and sidewall step coverage of 58% for a 155.6 nm opening trench with an aspect ratio of 9.

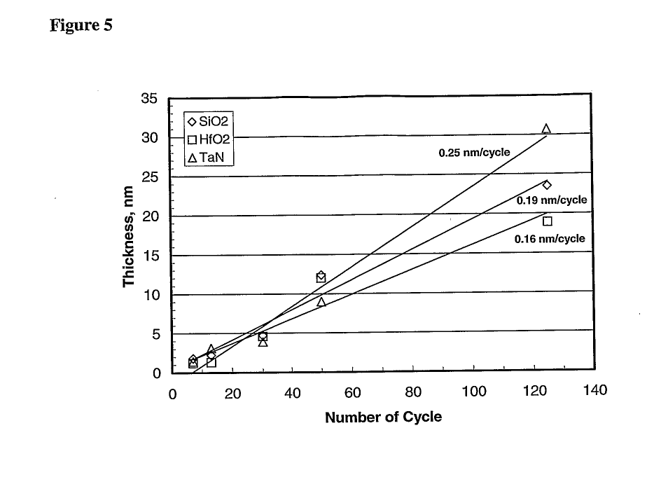

Run number 13-16 shows the seed study conducted under optimal deposition conditions. Formation of continuous ruthenium thin films at 1-2 nm thickness with only 7 deposition cycles indicates excellent seed with this precursor. Growth rates for those runs in the incubation/seed period are plotted in FIG. 5, showing averages of 0.16 to 0.25 nm/cycle on different substrates. These values are three to five times faster than those reported on state-of-the-art ruthenium precursors.

Low resistivity, high deposition rate, low surface roughness with low impurities and excellent seed are critical for applications such as DRAM capacitor bottom electrode and interconnect diffusion barrier/seed layer applications.

### Example 32

### PEALD of Ruthenium Films with NH₃ Plasma Using [1-(Ethylmethylamino)Ethyl]Ruthenocene, C₅H₅—Ru—O₅H₄—CH(CH₃)N(CH₃)(C₂H₅) (3B)

Ruthenium films were deposited by PEALD using NH₃ plasma and [1-(ethymethylamino)ethyl]ruthenocene (3B) as ruthenium containing precursor. Three different types of substrates, such as 1 μm SiO₂, 18 nm HfO₂, patterned PVD and ALD TaN were used to deposit the ruthenium films and deposition conditions are described in Table 8. Film thickness was analyzed using cross sectional field emission scanning electron microscopy. Detailed deposition conditions and the results are shown in Table 9, and the results illustrate that the PEALD Ru films made from the 3B precursor exhibit growth rates and electrical properties that are superior to those made from any other known ruthenium precursor.

TABLE 8
PEALD processing conditions

| Chamber pressure | 0.7 Torr |
|---|---|
| Plasma power | 150-300 W |
| Plasma frequency | 90 kHz |
| Ruthenium precursor 3A pulse length | 5-15 seconds |
| Ar/NH₃/Ar pulse length | 50 seconds/50 |
| | seconds/50 seconds |
| Ruthenium precursor 3B flow rate | 0.5 sccm |
| Ar flow rate | 50 sccm |
| N₂ flow rate | 50 sccm |
| Substrate temperature | 275-375° C. |
| Number of deposition cycles | 125-175 |

TABLE 9

| | | | | Ru | | | | | | | | |
|---|---|---|---|---|---|---|---|---|---|---|---|---|
| | | | | precursor | Film thickness | | | Deposition rate | | | Resistivity | |
| | | | Plasma | (3B) | (nm) | | | (nm/cycle) | | | (μΩ-cm) | |
| | T | | power | pulse | On | On | On | On | On | On | On | On |
| Run | (C.) | Cycles | (W) | time (s) | SiO₂ | HfO₂ | TaN | SiO₂ | HfO₂ | TaN | SiO₂ | HfO₂ |
| 1 | 275 | 125 | 300 | 15 | 18.9 | 17.8 | 37.2 | 0.15 | 0.14 | 0.3 | 17 | 16 |
| 2 | 275 | 150 | 150 | 15 | 13.8 | 20.3 | 16.4 | 0.09 | 0.14 | 0.11 | 27 | 16 |
| 3 | 375 | 125 | 300 | 15 | 28.3 | 31.3 | 31.7 | 0.23 | 0.25 | 0.25 | 13 | 12 |
| 4 | 275 | 150 | 300 | 5 | 20.1 | 23.5 | 20.1 | 0.13 | 0.16 | 0.13 | 13 | 12 |
| 5 | 275 | 175 | 150 | 5 | 16.6 | 17.2 | 12.6 | 0.1 | 0.1 | 0.07 | 20 | 15 |

### Example 33

### Annealing Data for the Ruthenium Films Deposited Using 1-Hydroxyethylruthenocene (2A)

In this Example, the ruthenium film samples that were deposited with ruthenium precursor pulse times of 1, 3 and 5 seconds were annealed at 600° C. for 1 minute in nitrogen. Each sample was characterized by utilizing 4PP, XPS, XRD, AFM, SEM and peel-off tests. It was discovered that resistivity decreases after annealing. In addition, all of the samples passed the peel-off test except the 5 second sample. The films “preferred” the 002 orientation after annealing and there was significant grain growth and roughness that increased during annealing. The data collected is shown in Table 10.

TABLE 10
Annealing data for the ruthenium films deposited using 1-
hydroxyethylruthenocene (2A)

| | | 1-HYDRO- | | |
|---|---|---|---|---|
| | | XYETHYLRUTHENOCENE | | |
| | | (2A) pulse time | | |
| | | 1 sec | 3 sec | 5 sec |
| Resistivity (uohm-cm) | as-deposited | 20 | 40 | 52 |
| | annealed | 11 | 14 | 17 |
| Peel-off test | as-deposited | pass | pass | pass |
| | annealed | pass | pass | fail |
| Crystallinity | as-deposited | 002 | random | random |
| | annealed | 002 | 002 | 002 |

Thus, specific embodiments, methods of use and applications of organometallic precursors and related intermediates for deposition processes, their production and methods of use have been disclosed. It should be apparent, however, to those skilled in the art that many more modifications besides those already described are possible without departing from the inventive concepts herein. The graphical interface presented to the user may vary from those graphical interfaces depicted in this subject matter without departing from the inventive concepts. The inventive subject matter, therefore, is not to be restricted except in the spirit of the disclosure herein. Moreover, in interpreting the specification, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

1-18. (canceled)

19. A process of depositing the vapor deposition precursor of the formula CMC′, comprising:
heating the vapor deposition precursor to form a vapor of the precursor;
exposing a substrate surface to the vapor to form a layer of the precursor on the surface;
removing any excess precursor that is not adsorbed on the substrate;
reacting a reactant with the layer to form a thin film on the surface and a by-product; and
removing excess of the reactant and the by-product, wherein
M comprises a metal or a metalloid;
C comprises an acyclic alkene or cycloalkene ring structure; and
C′ comprises an acyclic alkene or cycloalkene ring structure; wherein
at least one of C and C′ further and individually is substituted with a ligand represented by the formula CH(X)R₁, wherein X comprises OH, SH, NH₂, NH(R₂), or N(R₂R₃), R₁ is hydrogen, or primary, secondary and tertiary alkyl group with a general formula CₙH₂ₙ₊₁ where n=1-6, or cycloalkyl, R₂ and R₃ can be the same or different and comprise primary, secondary or tertiary alkyl groups with a general formula CₙH₂ₙ₊₁ where n=1-6, or cycloalkyl.

20. The process of claim 19, wherein the substrate comprises crystalline or amorphous silicon, silicon oxide, silicon dioxide, silicon nitride, silicon oxynitrides soda lime glass, a seed layer of aluminum oxide, tantalum nitride, titanium nitride, tungsten nitride, tungsten carbonitride, titanium aluminum nitride, ruthenium, iridium, platinum, tungsten, copper, aluminum, nickel, tantalum, titanium silicides, hafnium oxide, zirconium oxide, tantalum oxide, titanium oxide, hafnium silicate, strontium titanate, barium strontium titanate, or a combination thereof.

21. The process of claim 19, wherein the reactant comprises air, oxygen, nitrous oxide, nitric oxide, nitrogen dioxide, nitrogen pentoxide, hydrogen peroxide, hydrogen, atomic hydrogen, ammonia, silane, disilane, trisilane, tetrasilane, methylsilane, ethylsilane, propylsilane, phenylsilane, diphenylsilane, fluorosilane, chlorosilane, bromosilane, iodosilane, borane, diborane, triborane, tetraborane, pentaborane, methylborane, ethylborane, propylborane, butylborane, derivatives thereof, or a combination thereof.

22. The process of claim 19, further comprising post-treatment of the film.

23. The process of claim 22, wherein
M is ruthenium; and
the post-treatment comprises annealing, wherein the post-treatment results in densification of the film, reduction of impurities and improved conductivity of the film, preferred growth of ruthenium grains along (002) orientation, or a combination thereof.

24. A thermal ALD process of depositing the vapor deposition precursor of the formula CMC′, comprising:
providing the vapor deposition precursor;
providing a substrate in a deposition chamber;
heating the vapor deposition precursor to a source temperature of 50-200° C.;
heating the substrate in a vacuum or inert atmosphere to a temperature of 200 to 500° C.;
introducing the precursor into the chamber with or without a carrier gas;
adsorbing the precursor onto the substrate to form a layer;
providing a time where the precursor can form a layer on the substrate, wherein the time is less than 50 seconds;
removing excess precursor that is not adsorbed to the substrate;
introducing a reactant;
allowing the reactant to react with the layer for less than 50 seconds to form a film and a by-product; and
removing excess of the reactant and the by-product, wherein
M comprises a metal or a metalloid;
C comprises an acyclic alkene or cycloalkene ring structure; and
C′ comprises an acyclic alkene or cycloalkene ring structure; wherein at least one of C and C′ further and individually is substituted with a ligand represented by the formula CH(X)R₁, wherein X comprises OH, SH, NH₂, NH(R₂), or N(R₂R₃), R₁ is hydrogen, or primary, secondary and tertiary alkyl group with a general formula CₙH₂ₙ₊₁ where n=1-6, or cycloalkyl, R₂ and R₃ can be the same or different and comprise primary, secondary or tertiary alkyl groups with a general formula CₙH₂ₙ₊₁ where n=1-6, or cycloalkyl.

25. The process of claim 24, wherein the process comprises a cycle, M is ruthenium and the film growth rate is at least 0.02 nm/cycle.

26. A PEALD process of depositing the vapor deposition precursor of the formula CMC′, comprising:
providing the vapor deposition precursor;
providing a substrate in a deposition chamber;
heating the vapor deposition precursor to a source temperature of 50-200° C.;
heating the substrate in a vacuum or inert atmosphere to a temperature of 200 to 450° C.;
introducing the precursor into the chamber with or without a carrier gas, wherein the carrier gas comprises inert gas, reactant gas or a combination thereof;
adsorbing the precursor onto the substrate;
providing a time where the precursor can form a layer on the substrate, wherein the time is less than 50 seconds;
removing excess precursor that is not adsorbed to the substrate;
introducing a reactant;
introducing a plasma into at least part of the chamber to at least activate the reactant;
allowing the reactant to react with the layer for less than 50 seconds to form a film and a by-product; and
removing excess of the reactant and the by-product, wherein
M comprises a metal or a metalloid;
C comprises an acyclic alkene or cycloalkene ring structure; and
C′ comprises an acyclic alkene or cycloalkene ring structure; wherein at least one of C and C′ further and individually is substituted with a ligand represented by the formula CH(X)R₁, wherein X comprises OH, SH, NH₂, NH(R₂), or N(R₂R₃, R₁ is hydrogen, or primary, secondary and tertiary alkyl group with a general formula CₙH₂ₙ₊₁ where n=1-6, or cycloalkyl, R₂ and R₃ can be the same or different and comprise primary, secondary or tertiary alkyl groups with a general formula CₙH₂ₙ₊₁ where n=1-6, or cycloalkyl.

27. The process of claim 26, wherein the reactant is at least partially activated remotely from the chamber.

28. A PEALD process of depositing the vapor deposition precursor of the formula CMC′, comprising:
providing a substrate in a deposition chamber;
introducing the vapor deposition precursor and a reactant into the chamber; and
pulsing a plasma in at least part of the chamber, wherein
M comprises a metal or a metalloid;
C comprises an acyclic alkene or cycloalkene ring structure; and
C′ comprises an acyclic alkene or cycloalkene ring structure; wherein at least one of C and C′ further and individually is substituted with a ligand represented by the formula CH(X)R₁, wherein X comprises OH, SH, NH₂, NH(R₂), or N(R₂R₃), R₁ is hydrogen, or primary, secondary and tertiary alkyl group with a general formula CₙH₂ₙ₊₁ where n=1-6, or cycloalkyl, R₂ and R₃ can be the same or different and comprise primary, secondary or tertiary alkyl groups with a general formula CₙH₂ₙ₊₁ where n=1-6, or cycloalkyl.

29. The process of claim 26, wherein the plasma is operated at 0.05-3 W/cm².

30. The process of claim 26, wherein the process comprises a cycle, M is ruthenium and the film growth rate is at least 0.05 nm/cycle.

31. The process of claim 26, wherein the precursor is adsorbed to form a ruthenium film, wherein the film has a resistivity of 50 μΩ-cm or less when measured at a thickness of 10 nm.

32. A ruthenium film made by the process of claim 31, wherein the film has a growth rate of at least 0.05 nm/cycle, and an average surface roughness of less than 1 nm RMS.

33. An electrode for DRAM, FRAM or MRAM applications, comprising a ruthenium or ruthenium oxide film formed by the process of claim 19, on a silicon substrate, wherein M is ruthenium.

34. A gate stack for CMOS logic, comprising ruthenium films formed by the process of claim 19, wherein M is ruthenium.

35. A MRAM structure, comprising a ruthenium metal channel layer with an average thickness of 0.5-1.5 nm, formed by the process of claim 19, wherein M is ruthenium.

36. A copper interconnect, comprising a layer of ruthenium formed by the process of claim 19, wherein M is ruthenium.

37-39. (canceled)

40. A coated structure produced by the process of claim 19.

41. The coated structure of claim 40, comprising ruthenium, RuO₂, RuO, Ru₂O₃, mixed oxides, ruthenium nitride, ruthenium silicide, or a combination thereof, wherein M is ruthenium.

42. A powder produced by the process of claim 19.

43. The powder of claim 42, comprising ruthenium, RuO₂, RuO, Ru₂O₃, mixed oxides, ruthenium nitride, ruthenium silicide, or a combination thereof, wherein M is ruthenium.

44. A coating produced by the process of claim 19.

45. The coating of claim 44, comprising ruthenium, RuO₂, RuO, Ru₂O₃, mixed oxides, ruthenium nitride, ruthenium silicide, or a combination thereof, wherein M is ruthenium.

46. A film produced by the process of claim 19.

47. The film of claim 46, comprising ruthenium, RuO₂, RuO, Ru₂O₃, mixed oxides, ruthenium nitride, ruthenium silicide, or a combination thereof, wherein M is ruthenium.

48. The process of claim 19, wherein the acyclic alkene comprises pentadiene or heptadiene, and the cycloalkene comprises cyclopentadiene, cycloheptatriene, cycloctatetraene or indene.

49. The process of claim 19, wherein acyclic alkene comprises pentadiene, and the cycloalkene comprises cyclopentadiene.

50. The process of claim 19, comprising the vapor deposition precursor of the formula CM[C₅H₄—CH(R₁)NR₂R₃].

51. The process of claim 19, wherein M comprises group 8 metals.

52. The process of claim 19, wherein M is ruthenium.

53. The process of claim 19, comprising the vapor deposition precursor of:
C₅H₅RuC₅H₄CH[N(CH₃)₂]CH₃;
C₅H₅RuC₅H₄CH[N(CH₃)(C₂H₅)]CH₃;
C₅H₅RuC₅H₄CH[N(CH₃)(ⁿC₄H₉)]CH₃;
C₅H₅RuC₅H₄CH[N(C₂H₅)₂]CH₃;
C₅H₅RuC₅H₄CH[N(CH₃) (^{l}C₃H₇)]CH₃;
C₅H₅RuC₅H₄CH[N(CH₃)(C₃H₇)]CH₃;
C₅H₅RuC₅H₄CH[N(^{l}C₃H₇)(C₂H₅)]CH₃;
C₅H₅RuC₅H₄CH[N(C₃H₇)(ⁿC₄H₉)]CH₃;
C₅H₅RuC₅H₄CH[N(ⁿC₃H₇)₂]CH₃;
C₅H₅RuC₅H₄CH[N(^{l}C₃H₇)₂]CH₃;
C₅H₅RuC₅H₄CH[N(CH₃)(C₆H₁₁)]CH₃;
C₅H₅RuC₅H₄CH₂[N(CH₃)₂];
C₅H₅RuC₅H₄CH₂[N(CH₃)(C₂H₅)];
C₅H₅RuC₅H₄CH₂[N(CH₃)(ⁿC₄H₉)];
C₅H₅RuC₅H₄CH₂[N(C₂H₅)₂];
[CH₂═C(CH₃)CHC(CH₃)═CH₂]RuC₅H₄CH(OH)CH₃; [CH₂═C(CH₃)CHC(CH₃)═CH₂]RuC₅H₄CH[N(CH₃)₂]CH₃;
[CH₂═C(CH₃)CHC(CH₃)═CH₂]RuC₅H₄CH[N(CH₃)(C₂H₅)]CH₃;
[CH₂═C(CH₃)CHC(CH₃)═CH₂]RuC₅H₄CH[N(ⁿC₄H₉)(CH₃)]CH₃; or
[CH₂═C(CH₃)CHC(CH₃)═CH₂]RuC₅H₄CH[N(C₂H₅)₂]CH₃.
